(19) United States
(12) Patent Application Publication
(10) Pub. No.: US 2026/0164766 A1
(43) Pub. Date: Jun. 11, 2026

(54) SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Ryutaro ISHIZAKI, Matsumoto-city (JP)

(21) Appl. No.: 19/369,304

(22) Filed: Oct. 26, 2025

(30) Foreign Application Priority Data
Dec. 11, 2024 (JP) 2024-216435

(51) Int. Cl. H10D 84/00; H10D 12/00; H10D 62/10; H10D 84/01

(52) U.S. Cl. CPC H10D 84/161; H10D 12/415; H10D 12/481; H10D 62/107; H10D 84/0109

(57) ABSTRACT

Provided is a semiconductor device including: a semiconductor substrate which has an upper surface and a lower surface and is provided with a drift region of a first conductivity type; an active portion which is provided in the semiconductor substrate; and an edge termination structure portion which is provided in the semiconductor substrate and provided between the active portion and an end portion of the semiconductor substrate at the upper surface of the semiconductor substrate, in which the edge termination structure portion includes an interlayer dielectric film which is provided on the upper surface of the semiconductor substrate, and a guard ring of a second conductivity type which is provided in the semiconductor substrate and is at least partially in contact with the interlayer dielectric film at the upper surface of the semiconductor substrate.

The contents of the following patent application(s) are incorporated herein by reference:
No. 2024-216435 filed in JP on Dec. 11, 2024.

### BACKGROUND

### 1. Technical Field

The present invention relates to a semiconductor device.

### 2. Related Art

Conventionally, a semiconductor device having a termination structure is known (see, for example, Patent Document 1).
Patent Document 1: International Publication No. WO 2024/100926

### BRIEF DESCRIPTION OF THE DRAWINGS

FIG. 1 is a top view illustrating an example of a semiconductor device 100 according to one embodiment of the present invention.

FIG. 2 is an enlarged view of a region D in FIG. 1.

FIG. 3 is a view illustrating an example of a cross section e-e in FIG. 2.

FIG. 4 is an enlarged view of a mesa portion 60 in FIG. 3.

FIG. 5A is a diagram illustrating a doping concentration distribution in a depth direction of the mesa portion 60.

FIG. 5B is a diagram illustrating another example of the doping concentration distribution in the depth direction of the mesa portion 60.

FIG. 6 is an enlarged view illustrating another example of the mesa portion 60.

FIG. 7 is a diagram illustrating a concentration distribution of bulk donors along a line h-h′ of FIG. 6.

FIG. 8 is a diagram illustrating a first modification of the mesa portion 60.

FIG. 9A is a diagram illustrating the doping concentration distribution in the depth direction of the mesa portion 60.

FIG. 9B is a diagram illustrating another example of the first modification of the mesa portion 60.

FIG. 9C is a diagram illustrating another example of the doping concentration distribution in the depth direction of the mesa portion 60.

FIG. 9D is a diagram illustrating another example of the first modification of the mesa portion 60.

FIG. 9E is a diagram illustrating another example of the doping concentration distribution in the depth direction of the mesa portion 60.

FIG. 10 is a diagram illustrating a second modification of the mesa portion 60.

FIG. 11 is a diagram illustrating a third modification of the mesa portion 60.

FIG. 12 is a diagram illustrating a fourth modification of the mesa portion 60.

FIG. 13 is a diagram illustrating an example of a manufacturing step of a semiconductor device 100.

FIG. 14A is a diagram for explaining a trench formation step S1010.

FIG. 14B is a diagram for explaining an implantation step S1020 for a trench bottom region 109.

FIG. 14C is a diagram for explaining an implantation step S1030 for an accumulation region 16.

FIG. 14D is a diagram for explaining an implantation step S1040 for a base region 14.

FIG. 14E is a diagram for explaining an annealing step S1050.

FIG. 15A is a diagram for explaining another example of the implantation step S1040 of the base region 14.

FIG. 15B is a diagram for explaining another example of the annealing step S1050.

FIG. 16 is a diagram illustrating another example of a manufacturing step of the semiconductor device 100.

FIG. 17A is a diagram for explaining an implantation step S1050 for the accumulation region 16 in FIG. 16.

FIG. 17B is a diagram for explaining a second annealing step S1060 in FIG. 16.

FIG. 18A is a diagram for explaining another example of the implantation step S1050 for the accumulation region 16 in FIG. 16.

FIG. 18B is a diagram for explaining another example of the second annealing step S1060 in FIG. 16.

FIG. 19 is a view illustrating an example of a cross section b-b in FIG. 1.

FIG. 20 is an enlarged view of a semiconductor substrate 10 in a vicinity of a well region 17 and a guard ring 92 in FIG. 19.

FIG. 21 is a view illustrating another example of the guard ring 92.

FIG. 22 is a view illustrating another example of the guard ring 92.

FIG. 23 is a diagram illustrating a concentration distribution of bulk donors along a line i-i′ of FIG. 22.

FIG. 24 is a view illustrating the guard ring 92 in a comparative example.

FIG. 25 is a diagram illustrating an example of a manufacturing step of an edge termination structure portion 90.

FIG. 26A is a diagram for explaining an implantation step S2010 for the guard ring 92.

FIG. 26B is a diagram for explaining an annealing step S2020.

FIG. 27A is a diagram for explaining another example of the implantation step S2010 for the guard ring 92.

FIG. 27B is a diagram for explaining another example of the annealing step S2020.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. Note that a +Z axis direction and a −Z axis direction are directions opposite to each other. When a Z axis direction is described without describing a sign, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, a direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doping has been carried out with an impurity is described as a P type or an N type. In the present specification, the impurity may particularly mean either a donor of the N type or an acceptor of the P type, and may be described as a dopant. In the present specification, the doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding a donor concentration set as a positive ion concentration to an acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply referred to as the doping concentration.

The donor has a function of supplying electrons to the semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons.

A hydrogen donor may be a donor obtained by combination of at least a vacancy (V) and hydrogen (H). Alternatively, interstitial Si-H which is a combination of interstitial silicon (Si-i) in a silicon semiconductor and hydrogen, and CiOi-H which is a combination of interstitial carbon (Ci), interstitial oxygen (Oi), and hydrogen also function as the donor which supplies electrons. In the present specification, the VOH defect, the CiOi-H, or the interstitial Si-H may be referred to as the hydrogen donor.

In the semiconductor substrate in the present specification, bulk donors of the N type are distributed throughout. The bulk donor is a dopant donor substantially uniformly contained in an ingot during manufacturing of the ingot from which the semiconductor substrate is made. The bulk donor of the present example is an element other than hydrogen. A bulk donor dopant is, for example, phosphorus, antimony, arsenic, selenium, or sulfur, but is not limited to these. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in the present example is manufactured by the MCZ method. The substrate manufactured by the MCZ method has an oxygen concentration of 1×10¹⁷ to 7×10¹⁷/cm³. The substrate manufactured by the FZ method has an oxygen concentration of 1×10¹⁵ to 5×10¹⁶/cm³. When the oxygen concentration is high, the hydrogen donor tends to be easily generated. A bulk donor concentration may use a chemical concentration of the bulk donors distributed throughout the semiconductor substrate, or may be a value between 90% and 100% of the chemical concentration. In addition, as the semiconductor substrate, a non-doped substrate not containing a dopant such as phosphorus may be used. In that case, a bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Note that each concentration in the present invention may be a value at room temperature. As an example, a value at 300 K (Kelvin) (about 26.9° C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, as used herein, a description of a P++ type or an N++ type means a higher doping concentration than that of the P+ type or the N+ type. As used herein, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be defined as the donor concentration. Similarly, in a region of the P type, the carrier concentration of the region may be defined as the acceptor concentration. As used herein, the doping concentration of the region of the N type may be referred to as the donor concentration, and the doping concentration of the region of the P type may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average value of the concentration of the donor, acceptor or net doping in the region may be defined as a donor, acceptor or net doping concentration. In the present specification, atoms/cm³ or /m3³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. The semiconductor substrate may be silicon, silicon carbide, gallium nitride, diamond, or gallium oxide.

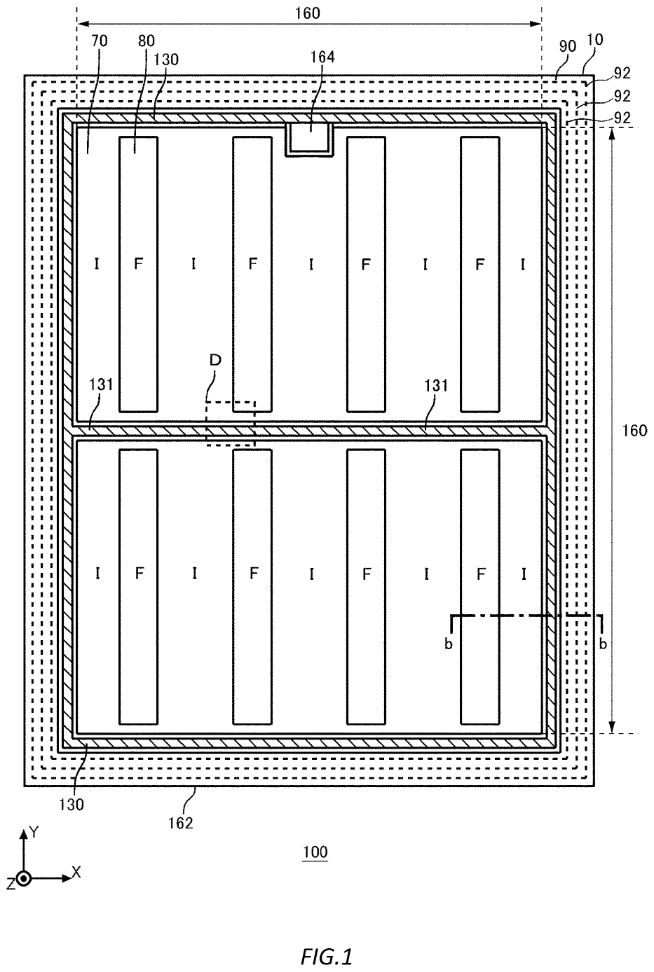

FIG. 1 is a top view illustrating an example of a semiconductor device 100 according to one embodiment of the present invention. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. As merely referred to as the top view in the present specification, it means that the semiconductor substrate 10 is viewed from the upper surface side. The semiconductor substrate 10 of the present example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region through which a main current flows in the depth direction between the upper surface and a lower surface of the semiconductor substrate 10 when the semiconductor device 100 operates. An emitter electrode is provided above the active portion 160, but illustration thereof is omitted in FIG. 1. The active portion 160 may refer to a region which overlaps with the emitter electrode in the top view. The active portion 160 may refer to a region where the emitter electrode and the semiconductor substrate 10 are in periodic contact with each other in the top view. In addition, a region sandwiched between active portions 160 in the top view may also be included in the active portion 160. For example, when the emitter electrode is separated into two, a region between the two emitter electrodes in the top view may also be included in the active portion 160.

The active portion 160 is provided with a diode portion 80 including a diode element such as a freewheeling diode (FWD). The active portion 160 may be further provided with a transistor portion 70 including a transistor element such as an insulated gate bipolar transistor (IGBT). In the example illustrated in FIG. 1, transistor portions 70 and diode portions 80 are alternately arranged along a predetermined array direction (the X axis direction in the present example) at the upper surface of the semiconductor substrate 10. The semiconductor device 100 of the present example is a reverse-conducting IGBT (RC-IGBT). The transistor portion 70 and the diode portion 80 are connected in antiparallel to each other. In other words, an emitter of the transistor portion 70 and an anode of the diode portion 80 are electrically connected, and a collector of the transistor portion 70 and a cathode of the diode portion 80 are electrically connected.

In FIG. 1, a region where the transistor portion 70 is arranged is indicated by a symbol “I”, and a region where the diode portion 80 is arranged is indicated by a symbol “F”. In the present specification, a direction perpendicular to the array direction in the top view may be referred to as an extending direction (the Y axis direction in FIG. 1). Each of the transistor portion 70 and the diode portion 80 may be elongated in the extending direction. In other words, a length of the transistor portion 70 in the Y axis direction is greater than a width in the X axis direction. Similarly, a length of the diode portion 80 in the Y axis direction is greater than a width in the X axis direction. The extending direction of the transistor portion 70 and the diode portion 80, and a longitudinal direction of each trench portion described later may be the same.

Each of the diode portions 80 includes a cathode region of the N+type in a region in contact with the lower surface of the semiconductor substrate 10. A region where the cathode region is arranged in the top view may be the diode portion 80. At the lower surface of the semiconductor substrate 10, a collector region of the P type may be provided in a region other than the diode portion 80.

The transistor portion 70 includes a collector region of the P type in a region in contact with the lower surface of the semiconductor substrate 10. In addition, in the transistor portion 70, an emitter region of the N type, a base region of the P type, and a gate structure including a gate conductive portion and a gate dielectric film are periodically arranged on the upper surface side of the semiconductor substrate 10.

The semiconductor device 100 may include one or more pads above the semiconductor substrate 10. The semiconductor device 100 of the present example includes a gate pad 164. The semiconductor device 100 may include a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner which connects the gate pad 164 and the gate trench portion. In FIG. 1, the gate runner is hatched with diagonal lines.

The gate runner of the present example includes an outer circumferential gate runner 130 and an active side gate runner 131. The outer circumferential gate runner 130 is arranged between the active portion 160 and the end side 162 of the semiconductor substrate 10 in the top view. The outer circumferential gate runner 130 of the present example encloses the active portion 160 in the top view. A region enclosed by the outer circumferential gate runner 130 in the top view may be the active portion 160. In addition, a well region is formed below the gate runner. The well region is a region of the P type having a higher concentration than a base region described later, and is formed from the upper surface of the semiconductor substrate 10 to a position deeper than the base region. A region enclosed by the well region in the top view may be the active portion 160.

The outer circumferential gate runner 130 is connected to the gate pad 164. The outer circumferential gate runner 130 is arranged above the semiconductor substrate 10. The outer circumferential gate runner 130 may be a metal wiring including aluminum or the like.

The active side gate runner 131 is provided in the active portion 160. Providing the active side gate runner 131 in the active portion 160 can reduce a variation in wiring length from the gate pad 164 for each region of the semiconductor substrate 10.

The outer circumferential gate runner 130 and the active side gate runner 131 are connected to the gate trench portion of the active portion 160. The outer circumferential gate runner 130 and the active side gate runner 131 are arranged above the semiconductor substrate 10. The outer circumferential gate runner 130 and the active side gate runner 131 may be either or both of a wiring formed of a semiconductor such as polysilicon doped with impurities or a metal wiring including aluminum or the like.

The active side gate runner 131 may be connected to the outer circumferential gate runner 130. The active side gate runner 131 of the present example is provided to extend in the X axis direction so as to cross the active portion 160 substantially at the center of the Y axis direction from one outer circumferential gate runner 130 to another outer circumferential gate runner 130 which sandwich the active portion 160. When the active portion 160 is divided by the active side gate runner 131, the transistor portion 70 and the diode portion 80 may be alternately arranged in the X axis direction in each divided region.

The semiconductor device 100 may include a temperature sensing portion (not illustrated) that is a PN junction diode formed of polysilicon or the like, and a current detection portion (not illustrated) that simulates an operation of the transistor portion provided in the active portion 160.

The semiconductor device 100 of the present example includes an edge termination structure portion 90 between the active portion 160 and the end side 162 in the top view. The edge termination structure portion 90 of the present example is arranged between the outer circumferential gate runner 130 and the end side 162. The edge termination structure portion 90 reduces an electric field strength at the upper surface side of the semiconductor substrate 10. The edge termination structure portion 90 may include at least one of a guard ring, a field plate, or a RESURF which are annularly provided enclosing the active portion 160. FIG. 1 illustrates a plurality of guard rings 92 annularly provided enclosing the active portion 160.

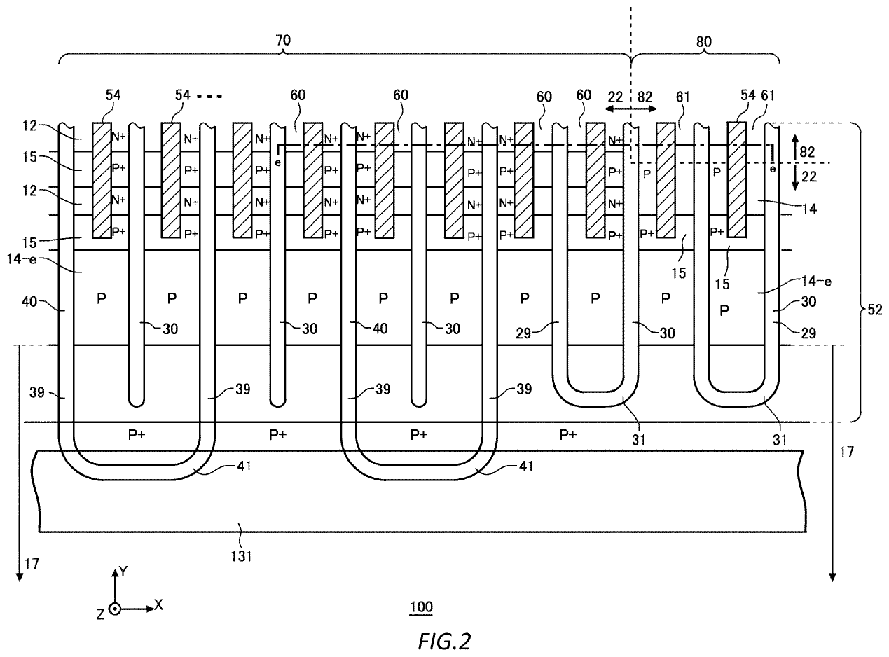

FIG. 2 is an enlarged view of a region D in FIG. 1. The region D is a region including the transistor portion 70, the diode portion 80, and the active side gate runner 131. The semiconductor device 100 of the present example includes a gate trench portion 40, a dummy trench portion 30, a well region 17, an emitter region 12, a base region 14, and a contact region 15 which are provided inside the upper surface side of the semiconductor substrate 10. The gate trench portion 40 and the dummy trench portion 30 each are an example of the trench portion. In addition, the semiconductor device 100 of the present example includes an emitter electrode 52 and the active side gate runner 131 which are provided above the upper surface of the semiconductor substrate 10. The emitter electrode 52 and the active side gate runner 131 are provided to be separate from each other.

An interlayer dielectric film is provided between the emitter electrode 52 and the active side gate runner 131, and the upper surface of the semiconductor substrate 10, but the interlayer dielectric film is omitted in FIG. 2. In the interlayer dielectric film of the present example, a contact hole 54 is provided to penetrate the interlayer dielectric film. In FIG. 2, each contact hole 54 is hatched with diagonal lines.

The emitter electrode 52 is provided above the gate trench portion 40, the dummy trench portion 30, the well region 17, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and the gate conductive portion, and may also be controlled to be at a potential different from a potential of the emitter electrode 52 and a potential of the gate conductive portion.

The active side gate runner 131 is connected to the gate trench portion 40 through the contact hole provided in the interlayer dielectric film. The active side gate runner 131 may be connected to a gate conductive portion of the gate trench portion 40 at an edge portion 41 of the gate trench portion 40 in the Y axis direction. The active side gate runner 131 is not connected to the dummy conductive portion in the dummy trench portion 30.

The emitter electrode 52 is formed of a material including a metal. FIG. 2 illustrates a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole. The emitter electrode 52 may be an electrode having a largest area in the top view.

The well region 17 is provided to overlap the active side gate runner 131. The well region 17 is provided to extend with a predetermined width even in a range not overlapping the active side gate runner 131. The well region 17 of the present example is provided away from an end of the contact hole 54 in the Y axis direction toward an active side gate runner 131 side. The well region 17 is a region of a second conductivity type which has a higher doping concentration than that of the base region 14. The base region 14 of the present example is the P type, and the well region 17 is the P+type.

Each of the transistor portion 70 and the diode portion 80 has a plurality of trench portions arrayed in the array direction. In the transistor portion 70 of the present example, one or more gate trench portions 40 and one or more dummy trench portions 30 are alternately provided along the array direction. In the diode portion 80 of the present example, a plurality of dummy trench portions 30 are provided along the array direction. In the diode portion 80 of the present example, the gate trench portion 40 is not provided.

The gate trench portion 40 of the present example may include two linear parts 39 extending along the extending direction perpendicular to the array direction (parts of a trench which are linear along the extending direction), and the edge portion 41 connecting the two linear parts 39. The extending direction in FIG. 2 is the Y axis direction.

At least a part of the edge portion 41 is preferably provided in a curved shape in the top view. By connecting between end portions of the two linear parts 39 in the Y axis direction by the edge portion 41, it is possible to reduce the electric field strength at the end portions of the linear parts 39.

In the transistor portion 70, the dummy trench portions 30 are provided between respective linear parts 39 of the gate trench portions 40. Between the respective linear parts 39, one dummy trench portion 30 may be provided or a plurality of dummy trench portions 30 may be provided. The dummy trench portion 30 may have a linear shape extending in the extending direction, or may include linear parts 29 and an edge portion 31 similarly to the gate trench portion 40. The semiconductor device 100 illustrated in FIG. 2 includes both the linear dummy trench portion 30 not having the edge portion 31 and the dummy trench portion 30 having the edge portion 31.

A diffusion depth of the well region 17 may be deeper than depths of the gate trench portion 40 and the dummy trench portion 30. The end portions in the Y axis direction of the gate trench portion 40 and the dummy trench portion 30 are provided in the well region 17 in the top view. In other words, a bottom portion in the depth direction of each trench portion is covered with the well region 17 at an end portion in the Y axis direction of each trench portion. With this configuration, the electric field strength at the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion of the present example is provided at the upper surface of the semiconductor substrate 10, so as to extend along the trench in the extending direction (Y axis direction). In the present example, a mesa portion 60 is provided in the transistor portion 70, and a mesa portion 61 is provided in the diode portion 80. When merely referred to as the mesa portion in the present specification, it may refer to each of the mesa portion 60 and the mesa portion 61.

The base region 14 is provided in each mesa portion. In the mesa portion, a region arranged closest to the active side gate runner 131, in the base region 14 exposed on the upper surface of the semiconductor substrate 10, is defined as a base region 14-e. While FIG. 2 illustrates the base region 14-e arranged at one end portion of each mesa portion in the extending direction, the base region 14-e is also arranged at another end portion of each mesa portion. In each mesa portion, a region sandwiched between the base regions 14-e in the top view may be provided with at least one of the emitter region 12 of a first conductivity type or the contact region 15 of the second conductivity type. The emitter region 12 of the present example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact region 15 and the emitter region 12 in the mesa portion 60 are alternately arranged along the extending direction of the trench portion (Y axis direction).

In another example, the contact region 15 and the emitter region 12 of the mesa portion 60 may be provided in a stripe shape along the extending direction of the trench portion (Y axis direction). For example, the emitter region 12 is provided in a region in contact with the trench portion, and the contact region 15 is provided in a region sandwiched between the emitter regions 12.

The emitter region 12 is not provided in the mesa portion 61 of the diode portion 80. The base region 14 and the contact region 15 may be provided at an upper surface of the mesa portion 61. In a region sandwiched between the base regions 14-e at the upper surface of the mesa portion 61, the contact region 15 may be provided in contact with each of the base regions 14-e. In a region sandwiched between the contact regions 15 at the upper surface of the mesa portion 61, the base region 14 may be provided. The base region 14 may be arranged in an entire region sandwiched between the contact regions 15.

The contact hole 54 is provided above each mesa portion. The contact hole 54 is arranged in a region sandwiched between the base regions 14-e. The contact hole 54 of the present example is provided above respective regions of the contact region 15, the base region 14, and the emitter region 12. In the diode portion 80, the contact region 15 may not be provided. The contact hole 54 is not provided in regions corresponding to the base region 14-e and the well region 17. The contact hole 54 may be arranged at a center of the mesa portion 60 in the array direction (X axis direction).

In the diode portion 80, a cathode region 82 is provided in a region in direct contact with the lower surface of the semiconductor substrate 10. At the lower surface of the semiconductor substrate 10, a collector region 22 of the P type may be provided in a region where the cathode region 82 is not provided. The cathode region 82 and the collector region 22 are provided between a lower surface 23 of the semiconductor substrate 10 and a buffer region 20. The cathode region 82 and the collector region 22 may be in contact with the lower surface 23 of the semiconductor substrate 10. In FIG. 2, a boundary between the cathode region 82 and the collector region 22 is indicated by a dotted line.

The cathode region 82 is arranged away from the well region 17 in the Y axis direction. With this configuration, a distance between a region of the P type (well region 17) having a relatively high doping concentration and formed up to a deep position and the cathode region 82 of the N+ type is ensured, so that a breakdown voltage can be improved. An end portion in the Y axis direction of the cathode region 82 of the present example is arranged farther away from the well region 17 than an end portion in the Y axis direction of the contact hole 54. In another example, the end portion in the Y axis direction of the cathode region 82 may be arranged between the well region 17 and the contact hole 54.

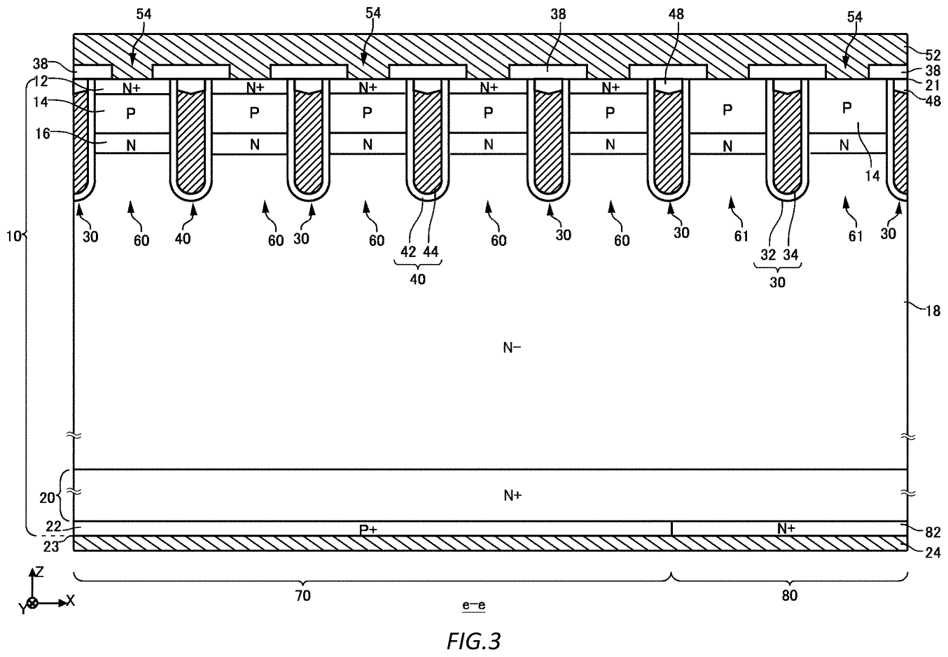

FIG. 3 is a view illustrating an example of a cross section e-e in FIG. 2. The cross section e-e is an XZ plane passing through the emitter region 12 and the cathode region 82. The semiconductor device 100 of the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus are added, a thermal oxide film, or other dielectric films. The interlayer dielectric film 38 is provided with the contact hole 54 described in FIG. 2.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided at the lower surface 23 of the semiconductor substrate 10. The emitter electrode 52 and the collector electrode 24 are formed of a metal material such as aluminum. In the present specification, a direction in which the emitter electrode 52 is connected to the collector electrode 24 (Z axis direction) is referred to as the depth direction.

The semiconductor substrate 10 includes a drift region 18 of the N type or the N− type. The drift region 18 is provided in each of the transistor portion 70 and the diode portion 80.

In the mesa portion 60 of the transistor portion 70, the emitter region 12 of the N+ type and the base region 14 of the P type are provided in order from an upper surface 21 side of the semiconductor substrate 10. The drift region 18 is provided below the base region 14. The mesa portion 60 may be provided with an accumulation region 16 of the N type. The accumulation region 16 is arranged between the base region 14 and the drift region 18. However, the accumulation region 16 may not be provided.

In the mesa portion 60, the emitter region 12 is provided between the base region 14 and the upper surface 21 of the semiconductor substrate 10. The emitter region 12 is exposed on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 of the present example is provided in contact with the emitter region 12. The base region 14 may be in contact with the trench portions on both sides of the mesa portion 60. However, a shape of the base region in a vicinity of the trench portion will be described later.

The accumulation region 16 is provided below the base region 14. The accumulation region 16 is a region of the N type having a higher doping concentration than that of the drift region 18. That is, the accumulation region 16 has a higher donor concentration than the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entire lower surface of the base region 14 in each mesa portion 60. Although the accumulation region 16 illustrated in FIG. 3 is provided only on the upper surface 21 side with respect to the lower end of the trench portion, in another example, the accumulation region 16 may be provided from an upper surface 21 side to a lower surface 23 side with respect to the lower end of the trench portion.

In the mesa portion 61 of the diode portion 80, the base region 14 of the P type is provided in contact with the upper surface 21 of the semiconductor substrate 10. The base region 14 of the diode portion 80 functions as an anode region of the diode portion 80. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may have two or more concentration peaks in the depth direction (Z axis direction) of the semiconductor substrate 10. The concentration peak of the buffer region 20 may be provided at a same depth position as a chemical concentration peak of hydrogen (proton) or phosphorus, for example. The buffer region 20 may function as a field stopper layer which prevents a depletion layer expanding from a lower end of the base region 14 from reaching the collector region 22 and the cathode region 82.

In the transistor portion 70, the collector region 22 of the P+type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In the diode portion 80, the cathode region 82 of the N+type is provided below the buffer region 20. A donor concentration of the cathode region 82 is higher than a donor concentration of the drift region 18. A donor of the cathode region 82 is, for example, arsenic, hydrogen, or phosphorus. A position where the collector region 22 and the cathode region 82 are in contact with each other may be a boundary between the transistor portion 70 and the diode portion 80 in the X axis direction.

The collector region 22 and the cathode region 82 are exposed on the lower surface 23 of the semiconductor substrate 10 and are connected to the collector electrode 24. The collector electrode 24 may be in contact with an entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided from the upper surface 21 of the semiconductor substrate 10 to a region below the base region 14, penetrating the base region 14. In a region where at least one of the emitter region 12, the contact region 15, or the accumulation region 16 is provided, each trench portion also penetrates doping regions of these. A structure in which the trench portion penetrates the doping region is not limited to a structure which is made by forming the doping region and then forming the trench portion in order. A structure in which the trench portion is formed and then the doping region is formed between the trench portions is also included in the structure in which the trench portion penetrates the doping region.

As described above, the transistor portion 70 is provided with the gate trench portion 40 and the dummy trench portion 30. The diode portion 80 is provided with the dummy trench portion 30 and is not provided with the gate trench portion 40.

The gate trench portion 40 is provided on the upper surface 21 side of the semiconductor substrate 10. The gate trench portion 40 of the present example includes a gate trench, a gate dielectric film 42, and a gate conductive portion 44. The gate dielectric film 42 is provided to cover an inner wall of the gate trench. The gate dielectric film 42 may be an oxide film formed by oxidizing a semiconductor on the inner wall of the gate trench or a nitride film formed by nitriding. For example, when the semiconductor substrate 10 is a silicon substrate, the gate dielectric film 42 may be a silicon oxide film.

The gate conductive portion 44 is provided inside the semiconductor substrate 10, and is provided farther inward than the gate dielectric film 42 inside the gate trench. Being provided inside the semiconductor substrate 10 may mean being positioned between the upper surface 21 and the lower surface 23 of the semiconductor substrate 10 in the depth direction. That is, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered with the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

An interlayer dielectric film 48 may be provided between the interlayer dielectric film 38 and the gate conductive portion 44 in the depth direction. The interlayer dielectric film 48 may be provided farther inward than the upper surface 21 of the semiconductor substrate 10. The interlayer dielectric film 48 of the present example is provided between the gate dielectric films 42 in the X axis direction. A position where the interlayer dielectric film 48 and the gate dielectric film 42 are in contact with each other may be on the upper surface 21 side with respect to an upper end of the base region 14. The interlayer dielectric film 48 may be formed of a same material as that of the interlayer dielectric film 38, or may be formed in a same step. Alternatively, the interlayer dielectric film 48 may be formed of a material different from that of the interlayer dielectric film 38, or may be formed in a different step therefrom. In another example, the interlayer dielectric film 48 may not be provided, and the upper surface of the gate conductive portion 44 may be aligned with the upper surface 21 of the semiconductor substrate 10.

The dummy trench portion 30 may have a same structure as that of the gate trench portion 40 in a cross section x-z of FIG. 3. The dummy trench portion 30 includes a dummy trench provided at the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of a same material as that of the gate conductive portion 44. For example, the dummy conductive portion 34 is formed of a conductive material such as polysilicon. The dummy conductive portion 34 may have a same length as that of the gate conductive portion 44 in the depth direction. In addition, the interlayer dielectric film 48 may also be provided between the dummy conductive portion 34 and the interlayer dielectric film 38.

The gate trench portion 40 and the dummy trench portion 30 of the present example are covered with the interlayer dielectric film 38 on the upper surface 21 of the semiconductor substrate 10. Note that bottom portions of the dummy trench portion 30 and the gate trench portion 40 may be formed in a curved-surface shape that is convex downward (a curved shape in the cross section).

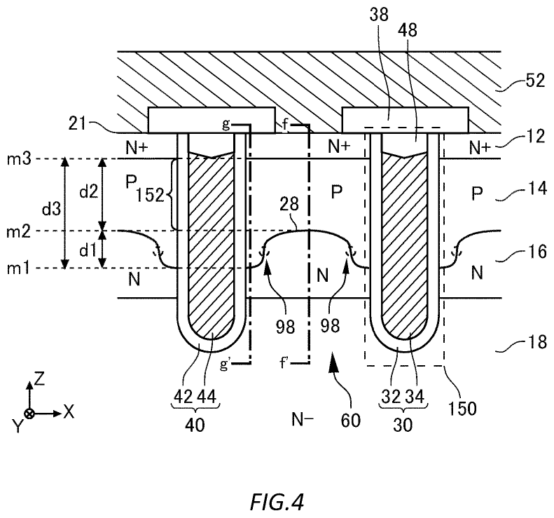

FIG. 4 is an enlarged view of the mesa portion 60 in FIG. 3. In FIG. 4, one of the trench portions sandwiching the mesa portion 60 is the gate trench portion 40. In the present specification, the trench portion arranged side by side with the gate trench portion 40 in the array direction may be referred to as an adjacent trench portion 150. The array direction of the present example is the X axis direction, and the adjacent trench portion 150 is the dummy trench portion 30. However, the adjacent trench portion 150 may be the gate trench portion 40. The mesa portion 60 of the present example is a region sandwiched between the gate trench portion 40 and the adjacent trench portion 150.

The emitter region 12, the base region 14, and the accumulation region 16 of the present example are in contact with a side wall part of the gate dielectric film 42. A lower end of the base region 14 at a part in contact with the gate dielectric film 42 is defined as a first end portion m1. In addition, the lower end of the base region 14 at a center in the array direction of the mesa portion 60 is defined as a second end portion m2.

The first end portion m1 of the present example is arranged at a position deeper than the second end portion m2. In the present specification, a depth of the structure provided on the upper surface 21 side is a distance in the Z axis direction with respect to the upper surface 21. That is, a distance between the first end portion m1 and the upper surface 21 is larger than a distance between the second end portion m2 and the upper surface 21. Note that a depth of the structure provided on the lower surface 23 side is a distance in the Z axis direction with respect to the lower surface 23. A gate-collector capacitance of the transistor portion 70 varies depending on an area of an impurity region in contact with the gate dielectric film 42. In the present example, the gate-collector capacitance varies depending on an area of the gate dielectric film 42 in contact with the accumulation region 16. Note that a region corresponding to the part where the gate dielectric film 42 and the base region 14 are in contact with each other may be referred to as a channel region 152. The channel region 152 may be a region where an inversion layer is formed when a voltage equal to or higher than a gate threshold is applied to a gate electrode electrically connected to the gate conductive portion 44. When an area of the channel region 152 increases, the area of the gate dielectric film 42 in contact with the accumulation region 16 decreases, and secondarily, the gate-collector capacitance decreases. Since the first end portion m1 is arranged at a position deeper than the second end portion m2, the gate-collector capacitance can be reduced, and a turn-on characteristic can be improved. Furthermore, since the second end portion m2 is arranged at a position shallower than the first end portion m1, it is possible to suppress influence of a variation in the doping concentration of the accumulation region 16 on a doping concentration distribution of the base region 14, particularly, a part in contact with a side wall of the gate trench portion 40. As a result, it is possible to suppress a variation in gate threshold voltage. Note that even when the accumulation region 16 is not provided and a part corresponding to the accumulation region 16 in FIG. 4 is the drift region 18, the second end portion m2 is arranged at a position shallower than the first end portion m1, whereby an area of the gate dielectric film 42 in contact with the drift region 18 decreases, so that an effect of reducing the gate-collector capacitance and an effect of suppressing the variation in gate threshold voltage are obtained. On the other hand, when the area of the channel region 152 increases, a gate-emitter capacitance increases, and a transconductance gm decreases. With this configuration, a saturation current value at a time of short circuit also decreases, and thus a short circuit tolerance is easily ensured. Such a shape of the base region 14 can be formed by adjusting a position of ion implantation or the like as described later.

A distance d1 in the depth direction between the first end portion m1 and the second end portion m2 may be 0.1 μm or more. As the distance d1 increases, an area of the channel region 152 described above can be increased. The distance d1 may be 0.2 μm or more, 0.3 μm or more, 0.4 μm or more, or 0.5 μm or more.

The distance d1 in the depth direction between the first end portion m1 and the second end portion m2 may be 1.0 μm or less. The distance d1 may be 0.9 μm or less, 0.8 μm or less, 0.7 μm or less, or 0.6 μm or less.

A lower end of the emitter region 12 is defined as m3. The lower end m3 of the emitter region 12 may be flat in the X axis direction. That is, a thickness in the depth direction of the emitter region 12 may be constant regardless of a position in the X axis direction. The lower end m3 of the emitter region 12 being flat may mean that a fluctuation in the thickness of the emitter region 12 is 10% or less, 5% or less, or 1% or less of an average thickness of the emitter region 12. A distance from the lower end m3 of the emitter region 12 at a part in contact with the gate dielectric film 42 to the first end portion m1 is defined as d3. In addition, a distance from the lower end m3 of the emitter region 12 at the center in the array direction of the mesa portion 60 to the second end portion m2 is defined as d2. The distance d3 of the present example is larger than the distance d2. The distance d3 and the distance d2 may be lengths in the depth direction (Z axis direction) of the base region 14 at respective positions in the X axis direction.

Also in a part of the mesa portion 60 in contact with the adjacent trench portion 150, the base region 14, the accumulation region 16, and the emitter region 12 may have shapes similar to those of a part in contact with the gate trench portion 40. When the adjacent trench portion 150 is the gate trench portion 40, also in the adjacent trench portion 150, the gate-collector capacitance can be reduced as described above, for example. A shape of the base region 14 in the XZ cross section may be line-symmetric with respect to a line crossing the center in the X axis direction of the mesa portion 60 in the depth direction. In addition, the shape illustrated in FIG. 4 may also be provided in another mesa portion 60 in which at least one of the trench portions sandwiching the mesa portion 60 is the gate trench portion 40.

In the array direction, a shape of a lower surface of the base region 14 may include a curved surface 28 that is convex toward the upper surface 21 of the semiconductor substrate 10. FIG. 4 illustrates a curve corresponding to the curved surface 28 of the lower surface of the base region 14. The curve of the lower surface of the base region 14 may have an inflection point 98. An inflection point is a point at which, when the curve is regarded as a function of z=f(x) in an XZ coordinate system, a sign of a second derivative f″(x) of the function changes. The lower surface of the base region 14 of the present example has one inflection point 98 between a position in contact with the gate dielectric film 42 and the center of the mesa portion 60 in the array direction. In addition, one inflection point 98 is provided between the center in the array direction of the mesa portion 60 and the adjacent trench portion 150. The curved surface 28 of the present example is a part between the inflection point 98 and the center in the array direction of the mesa portion 60 in the lower surface of the base region 14 in the XZ cross section. As illustrated in FIG. 4, when the base region 14 has a line-symmetrical shape with respect to a line crossing the center in the X axis direction of the mesa portion 60 in the depth direction, the curved surface 28 is a part between two inflection points 98 in the lower surface of the base region 14 in the XZ cross section.

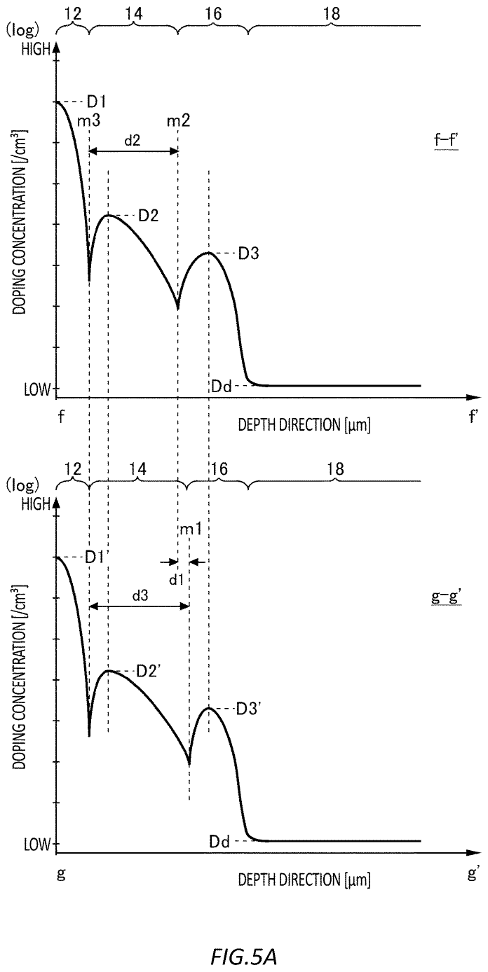

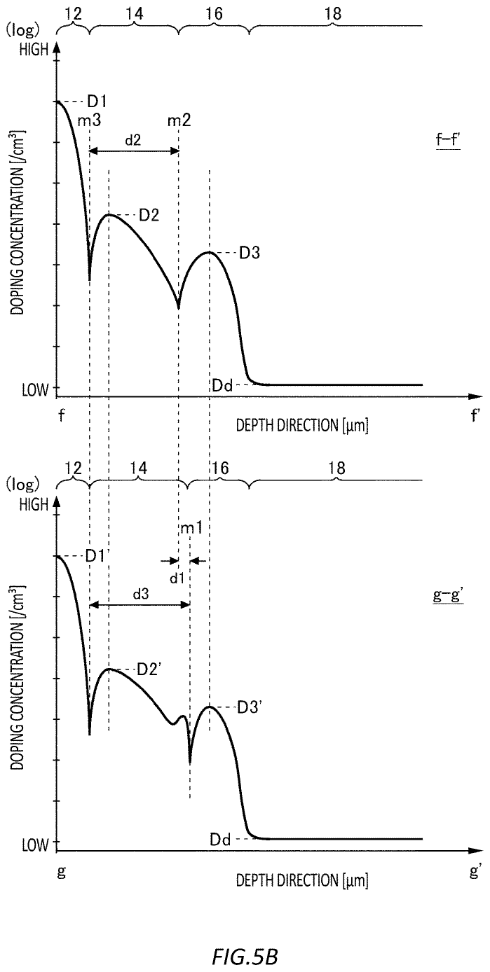

FIG. 5A is a diagram illustrating a doping concentration distribution in the depth direction of the mesa portion 60. FIG. 5A illustrates doping concentrations along a line f-f′ and a line g-g′ in FIG. 4. The line f-f′ is a line that extends to the drift region 18 across the emitter region 12, the base region 14, and the accumulation region 16 in the depth direction at the center in the array direction of the mesa portion 60. The line g-g′ is a line that extends to the drift region 18 across the emitter region 12, the base region 14, and the accumulation region 16 in the depth direction at a position in contact with the gate dielectric film 42. In FIG. 5A, a horizontal axis represents a position in the depth direction, and a vertical axis represents the doping concentration. In FIG. 5A, a doping concentration of the bulk donor is defined as Dd.

Each region may have a peak of the doping concentration. The doping concentration at a peak position of the emitter region 12 in the line f-f′ is defined as D1. Similarly, the doping concentration at a peak position of the base region 14 in the line f-f′ is defined as D2, and the doping concentration at a peak position of the accumulation region 16 is defined as D3. In addition, the doping concentration at a peak position of the emitter region 12 in the line g-g′ is defined as D1′. Similarly, the doping concentration at a peak position of the base region 14 in the line g-g′ is defined as D2′, and the doping concentration at a peak position of the accumulation region 16 is defined as D3′.

The doping concentration D1 and the doping concentration D1′ may be equal. The doping concentration D2 and the doping concentration D2′ may be equal. The doping concentration D3 and the doping concentration D3′ may be equal. As an example, the doping concentration D1 is 1×10²⁰/cm³, the doping concentration D2 is 2×10¹⁷/cm³, and the doping concentration D3 is 2×10¹⁶/cm³. A relationship of the doping concentrations may be D1>D2>D3 and D1′>D2′>D3′. Note that the doping concentration D2′ may be smaller than the doping concentration D2. In this case, the gate threshold may be determined by the doping concentration D2′.

The peak position of the emitter region 12 in the line f-f′ and the peak position of the emitter region 12 in the line g-g′ may be equal. The peak position of the base region 14 in the line f-f′ and the peak position of the base region 14 in the line g-g′ may be equal. The peak position of the accumulation region 16 in the line f-f′ and the peak position of the accumulation region 16 in the line g-g′ may be equal. However, at least one peak position may be different between the line f-f′ and the line g-g′.

A position of the first end portion m1 may be a position of a PN junction of the base region 14 and the accumulation region 16 in the line g-g′. A position of the second end portion m2 may be a position of the PN junction of the base region 14 and the accumulation region 16 in the line f-f′. When the accumulation region 16 is not provided, a position of a PN junction between the base region 14 and the drift region 18 may be the position of the first end portion m1 or the second end portion m2. A position of the lower end m3 may be a position of a PN junction of the emitter region 12 and the base region 14 in the line f-f′ or the line g-g′. An integrated value of the doping concentration of the base region 14 in the line g-g′ may be greater than or equal to an integrated value of the doping concentration of the base region 14 in the line f-f′. An integrated value of the doping concentration of the accumulation region 16 in the line g-g′ may be less than or equal to an integrated value of the doping concentration of the accumulation region 16 in the line f-f′.

FIG. 5B is a diagram illustrating another example of the doping concentration distribution in the depth direction of the mesa portion 60. FIG. 5B is different from the example of FIG. 5A in the doping concentration distribution in the depth direction of the base region 14. Other features of FIG. 5B may be the same as those of FIG. 5A. The base region 14 in the line g-g′ may have more doping concentration peaks in the depth direction than the base region 14 in the line f-f′. For example, in the example illustrated in FIG. 5B, the base region 14 may have a peak, which is smaller than the doping concentration D2′, at a position deeper than the peak of the doping concentration D2′. With this configuration, a thickness of the base region 14 in the line f-f′ can be easily made larger than a thickness of the base region 14 in the line g-g′. In this case, a dopant may be additionally implanted into the base region 14 in a vicinity of the line g-g′.

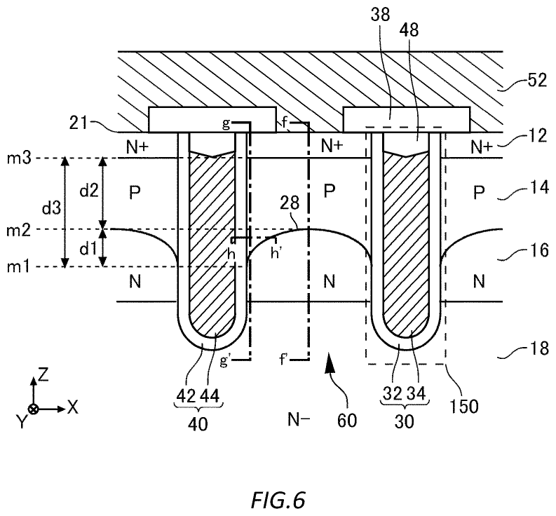

FIG. 6 is an enlarged view illustrating another example of the mesa portion 60. In the mesa portion 60 of the present example, the shape of the lower surface of the base region 14 is different from that of the base region 14 in FIG. 4. Other structures may be similar to those of the example of FIG. 4.

In the array direction, the shape of the lower surface of the base region 14 of the present example is a curved-surface shape that is convex toward the upper surface 21 of the semiconductor substrate 10. In other words, the lower surface of the base region 14 of the present example does not have the inflection point 98. In other words, in the XZ cross section, a surface between a position in the lower surface of the base region 14 in contact with the gate dielectric film 42 and the center in the array direction of the mesa portion 60 is the curved surface 28. Even with such a shape, an area of the accumulation region 16 in contact with the gate dielectric film 42 is reduced. Therefore, the above-described effect, such as being able to reduce the gate-collector capacitance, can be obtained.

When the gate dielectric film 42 is formed by oxidizing or nitriding the semiconductor substrate 10 or depositing an oxide film or the like, or when heating is performed after the formation, the bulk donor around the gate dielectric film 42 is incorporated into the gate dielectric film 42. Depending on a type of the bulk donor and an annealing condition at a time of forming the base region 14 or the like thereafter, how the bulk donor is incorporated into the gate dielectric film 42 from the mesa portion 60 varies.

Under the annealing condition of the base region 14 of a general IGBT, when the bulk donor is phosphorus, the bulk donor is easily incorporated into the gate dielectric film 42, and a phosphorus concentration in a part in contact with the gate dielectric film 42 increases. On the other hand, when the bulk donor is antimony, the bulk donor is less easily incorporated into the gate dielectric film 42. In that case, the gate dielectric film 42 contains antimony, and an antimony concentration in the part in contact with the gate dielectric film 42 remains reduced. In the mesa portion 60, the antimony concentration may decrease as approaching the gate dielectric film 42. In the base region 14, the antimony concentration may decrease as approaching the gate dielectric film 42. In the accumulation region 16, the antimony concentration may decrease as approaching the gate dielectric film 42.

When the concentration of the bulk donor in the part in contact with the gate dielectric film 42 is low, a junction with the base region 14 may have a shape such that it is positioned farther from the base region 14. In the part in contact with the gate dielectric film 42, a donor concentration of the bulk donor of the N type is low, and thus the doping concentration of the base region 14 in a vicinity of the junction may be relatively low. The doping concentration is a value obtained by subtracting the acceptor concentration from the donor concentration at a certain position. The semiconductor substrate 10 of the present example contains antimony as the bulk donor. Therefore, the base region 14 has a shape as illustrated in FIG. 6. When the semiconductor substrate 10 includes a plurality of types of bulk donors, the concentration of the antimony may be the highest.

The shape illustrated in FIG. 6 may be formed by adjusting a depth position of ion implantation or the like. For example, the shape can be formed by implanting the dopant of the base region 14 deeper as approaching the gate dielectric film 42. In addition, the doping concentrations in the line f-f′ and the line g-g′ may be similar to FIG. 5A or 5B.

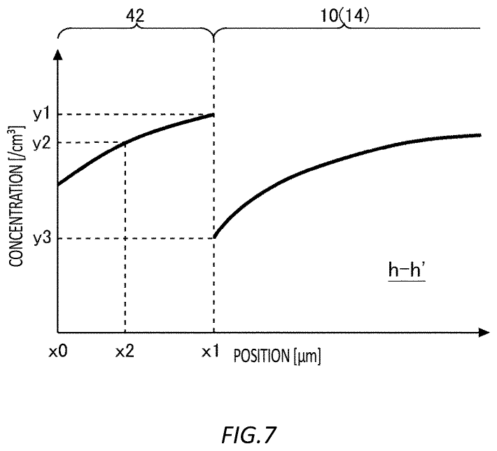

FIG. 7 is a diagram illustrating a chemical concentration distribution of a bulk donor dopant along a line h-h′ in FIG. 6. The line h-h′ is a line that extends to the base region 14 of the semiconductor substrate 10 across the gate dielectric film 42 in the array direction. In FIG. 7, a horizontal axis represents a position in the array direction, and a vertical axis represents a chemical concentration of the bulk donor dopant. As described above, the gate dielectric film 42 of the present example contains the bulk donor dopant (antimony). Hereinafter, the bulk donor dopant may be referred to as a bulk dopant.

A position x0 in FIG. 7 is a boundary between the gate dielectric film 42 and the gate conductive portion 44. A first position x1 is a position where the gate dielectric film 42 and the semiconductor substrate 10 are in contact with each other. The chemical concentration of the bulk dopant at the first position x1 is defined as y1. A second position x2 is a position in the gate dielectric film 42 farther from the semiconductor substrate 10 than the first position x1. The second position x2 may be a center in the array direction of the gate dielectric film 42, and may be equal to the position x0. The chemical concentration of the bulk dopant at the second position x2 is defined as y2.

The concentration y1 may be higher than the concentration y2. As described above, the gate dielectric film 42 allows incorporation of the bulk dopant from the semiconductor substrate 10, so that the chemical concentration of the bulk dopant at a position in contact with the semiconductor substrate 10 increases. The concentration y1 may be 1.2 times or more, 1.5 times or more, 2 times or more, 5 times or more, or 10 times or more the concentration y2. The concentration y1 may be a maximum value of the chemical concentration of the bulk dopant of the gate dielectric film 42. The chemical concentration of the bulk dopant of the gate dielectric film 42 may monotonously decrease from the first position x1 toward the position x0.

The chemical concentration of the bulk dopant of the base region 14 at the first position x1 is defined as y3. The concentration y3 may be lower than the concentration y1. As described above, the bulk dopant around the gate dielectric film 42 is incorporated into the gate dielectric film 42, so that the concentration y3 decreases. The concentration y3 may be lower than the concentration y2. The concentration y3 may be lower than a minimum value of the chemical concentration of the bulk dopant of the gate dielectric film 42.

In the semiconductor substrate 10, the chemical concentration of the bulk dopant in the drift region 18 may be higher than the chemical concentration of the bulk dopant at a position in contact with the gate dielectric film 42. As the chemical concentration of the bulk dopant in the drift region 18, an average value of the drift region 18 may be used. The position in contact with the gate dielectric film 42 may be a position (first position x1) in the base region 14 in contact with the gate dielectric film 42. In that case, the concentration of the bulk donor is defined as y3. A difference in the concentration may be 1.5 times or more, 2 times or more, 5 times or more, or 10 times or more.

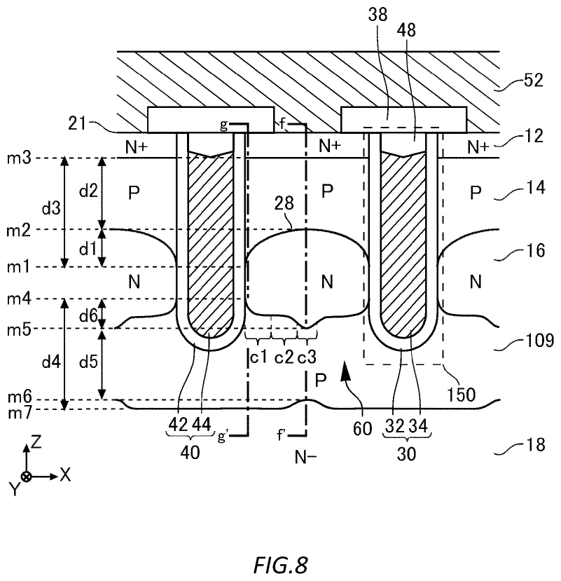

FIG. 8 is a diagram illustrating a first modification of the mesa portion 60. The semiconductor device 100 of the present example includes a trench bottom region 109 of the second conductivity type in addition to the mesa portion 60 illustrated in FIG. 6. The trench bottom region 109 is provided apart from the base region 14. In the present example, the accumulation region 16 is provided between the trench bottom region 109 and the base region 14. That is, the trench bottom region 109 is a floating region that is not electrically connected to the base region 14.

The trench bottom region 109 is in contact with the lower end of the gate trench portion 40. Providing the trench bottom region 109 can relax an electric field at the lower end of the gate trench portion 40. A part of the trench bottom region 109 is provided on the upper surface 21 side with respect to the lower end of the gate trench portion 40, and another part is provided on the lower surface 23 side with respect to the lower end of the gate trench portion 40. The trench bottom region 109 may be in contact with the lower end of the adjacent trench portion 150. The trench bottom region 109 may be provided continuously in the array direction from the gate trench portion 40 to the adjacent trench portion 150.

An upper end of the trench bottom region 109 at a part in contact with the gate dielectric film 42 is defined as m4. The upper end of the trench bottom region 109 at the center in the array direction of the mesa portion 60 is defined as m5. The upper end m4 may be located on the upper surface 21 side of the semiconductor substrate 10 with respect to the upper end m5. For a same reason as described above for the base region 14, the dopant of the trench bottom region 109 easily diffuses in a vicinity of the gate dielectric film 42, so that a shape illustrated in FIG. 8 is obtained. This further increases an area of the trench bottom region 109 in contact with the gate dielectric film 42. Therefore, the gate-collector capacitance can be further reduced, and the turn-on characteristic can be further improved. Note that even if the accumulation region 16 is not provided and a part corresponding to the accumulation region 16 in FIG. 8 is the drift region 18, the gate-collector capacitance can be reduced. The upper end m4 may be located closest to the upper surface 21 side in the trench bottom region 109. The bulk dopant of the present example is also antimony.

A distance d6 in the depth direction between the upper end m4 and the upper end m5 may be 0.1 μm or more. As the distance d6 increases, a contact area between the gate dielectric film 42 and the accumulation region 16 described above decreases, and the above-described effect such as reduction of the gate-collector capacitance can be obtained. The distance d6 may be 0.2 μm or more, 0.3 μm or more, 0.4 μm or more, or 0.5 μm or more.

The distance d6 in the depth direction between the upper end m4 and the upper end m5 may be 1.0 μm or less. The distance d1 may be 0.9 μm or less, 0.8 μm or less, 0.7 μm or less, or 0.6 μm or less. Note that the upper end m5 is recessed to the lower surface 23 side because a dopant is implanted from the bottom portion of the trench and diffused to form the trench bottom region 109 as described later. However, the upper end m5 may not be recessed to the lower surface 23 side. In the trench bottom region 109, the antimony concentration may decrease as approaching the gate dielectric film 42. In addition, the gate dielectric film 42 at a part in contact with the trench bottom region 109 may contain antimony.

A thickness of the trench bottom region 109 at a part in contact with the gate dielectric film 42 is defined as d4. The thickness d4 of the present example is a distance between the upper end m4 and a lower end m7 of the trench bottom region 109 at a horizontal position of the upper end m4. The thickness of the trench bottom region 109 at the center in the array direction of the mesa portion 60 is defined as d5. The thickness d5 of the present example is a distance between the upper end m5 and a lower end m6 of the trench bottom region 109 at the center in the array direction of the mesa portion 60. The thickness d4 may be larger than the thickness d5. Note that the lower end m6 may be recessed or may not be recessed to the upper surface 21 side for a reason similar to that in the upper end m5.

In the array direction, the upper end of the trench bottom region 109 may include a first curved surface c1 that is convex toward the lower surface 23 of the semiconductor substrate 10 in a direction of the gate dielectric film 42. Since FIG. 8 is a cross-sectional view, the first curved surface c1 is represented by a curve existing on the first curved surface c1. The curved surface being convex downward may mean that a line segment connecting two points on a curve existing on the curved surface is always above the curve. In this case, a point at which a first derivative is zero is not necessarily included between the two points. As described above, as approaching the gate dielectric film 42, the bulk dopant is incorporated into the gate dielectric film 42. Therefore, the dopant of the trench bottom region 109 is easily diffused. As a result, the shape illustrated in FIG. 8 is obtained. The first curved surface c1 of the trench bottom region 109 may be in contact with the gate dielectric film 42.

In the array direction, the upper end of the trench bottom region 109 may include a second curved surface c2 that is convex toward the upper surface 21 of the semiconductor substrate 10. Since FIG. 8 is a cross section, the second curved surface c2 is represented by a curve existing on the second curved surface c2. The curved surface being convex upward may mean that a line segment connecting two points on a curve existing on the curved surface is always below the curve. In this case, a point at which a first derivative is zero is not necessarily included between the two points. The second curved surface c2 of the present example is located on a center side in the array direction of the mesa portion 60 with respect to the first curved surface c1.

In the array direction, the upper end of the trench bottom region 109 may include a third curved surface c3 that is convex toward the lower surface 23 of the semiconductor substrate 10. Since FIG. 8 is a cross section, the third curved surface c3 is represented by a curve existing on the third curved surface c3. The third curved surface c3 may be located on a center side in the array direction of the mesa portion 60 with respect to the second curved surface c2. The third curved surface c3 of the present example is formed at the center in the array direction of the mesa portion 60.

In the array direction, the upper end of the trench bottom region 109 may have the first curved surface c1, the second curved surface c2, and the third curved surface c3 in order from the gate dielectric film 42 toward the adjacent trench portion 150. Since FIG. 8 is a cross section, in the array direction, the upper end of the trench bottom region 109 has the first curved surface c1, the second curved surface c2, and the third curved surface c3 in order from the gate dielectric film 42 toward the adjacent trench portion 150. Note that an inflection point may be provided between the curves existing on the respective curved surfaces.

Also in the part of the mesa portion 60 in contact with the adjacent trench portion 150, the trench bottom region 109 may have a shape similar to that of the part in contact with the gate trench portion 40. When the adjacent trench portion 150 is the gate trench portion 40, the gate-collector capacitance can be reduced also in the adjacent trench portion 150. A shape of the trench bottom region 109 in the XZ cross section may be line-symmetric with respect to a line crossing the center in the X axis direction of the mesa portion 60 in the depth direction. In addition, the shape illustrated in FIG. 8 or the like may also be provided in another mesa portion 60 in which at least one of the trench portions sandwiching the mesa portion 60 is the gate trench portion 40.

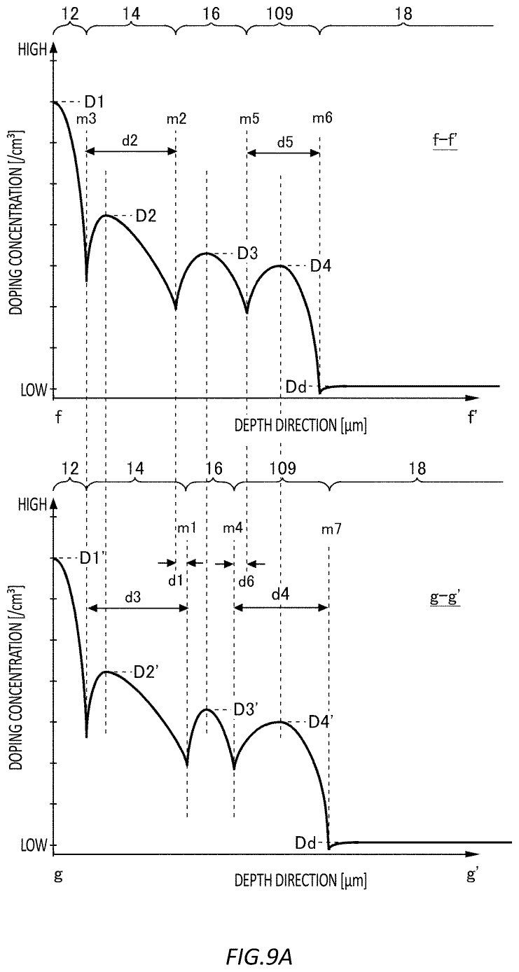

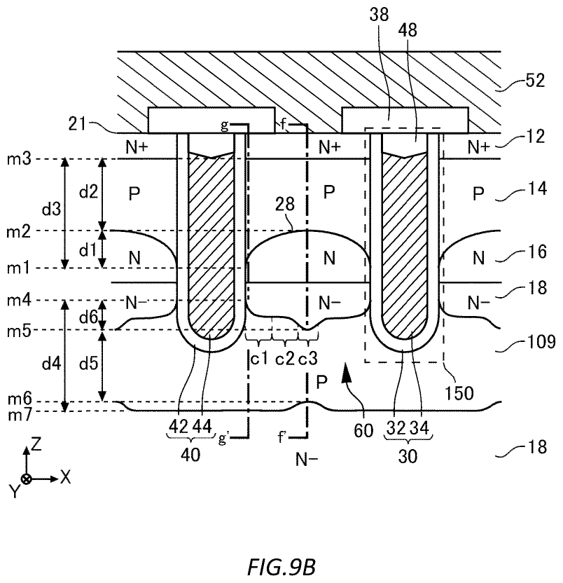

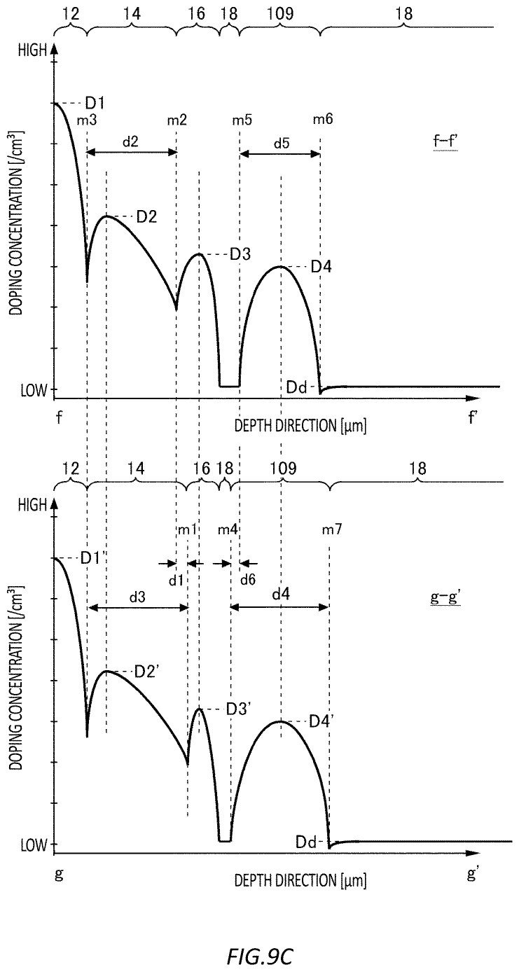

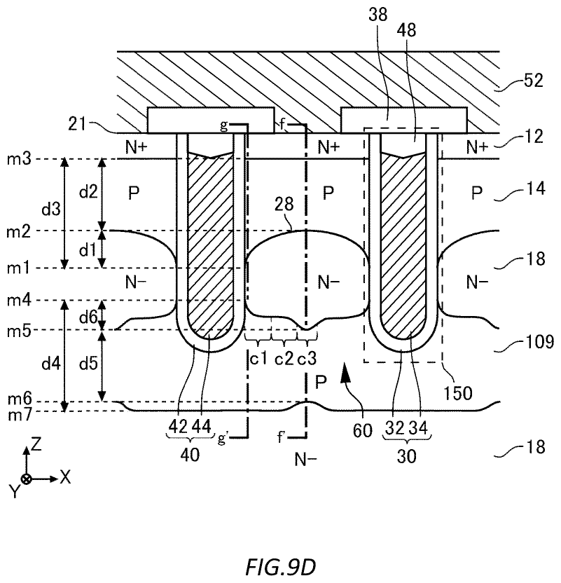

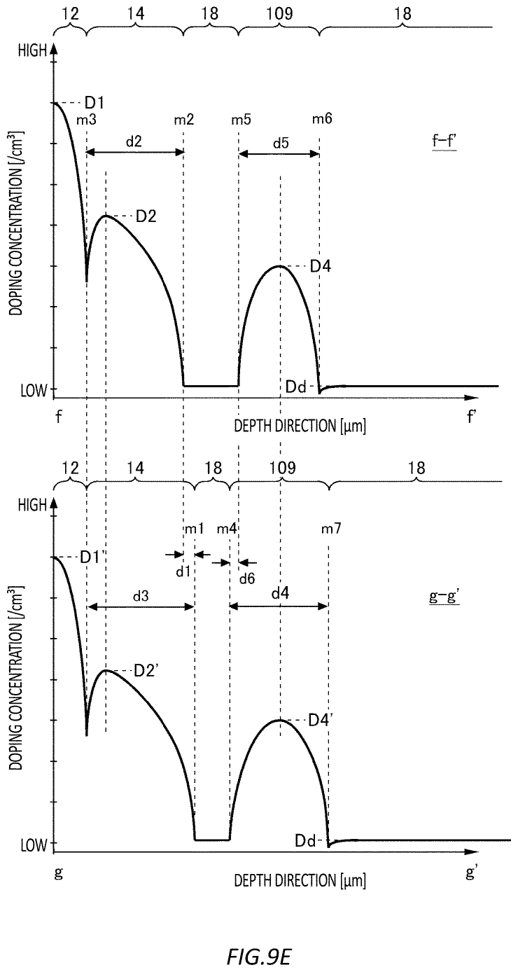

FIG. 9A is a diagram illustrating a doping concentration distribution in the depth direction of the mesa portion 60. FIG. 9A illustrates doping concentrations along the line f-f′ and the line g-g′ in FIG. 8. Positions of the line f-f′ and the line g-g′ are similar to those in FIG. 4. However, the line f-f′ and the line g-g′ of the present example also cross the trench bottom region 109. Since the emitter region 12, the base region 14, and the accumulation region 16 are similar to those in FIG. 5A, the description thereof is omitted.

The trench bottom region 109 may have a peak of the doping concentration. The doping concentration at a peak position of the trench bottom region 109 in the line f-f′ is defined as D4. In addition, the doping concentration at a peak position of the trench bottom region 109 in the line g-g′ is defined as D4′. The doping concentration D4 and the doping concentration D4′ may be equal. The doping concentration D4 may be smaller than the doping concentration D2 and may be smaller than the doping concentration D3. As an example, the doping concentration D4 is 1×10¹⁶/cm³. In another example, the doping concentration D4 may be greater than the doping concentration D3.

The peak position of the trench bottom region 109 in the line f-f′ and the peak position of the trench bottom region 109 in the line g-g′ may be equal or different. A position of the upper end m4 may be a position of a PN junction of the accumulation region 16 and the trench bottom region 109 in the line g-g′. A position of the upper end m5 may be a position of the PN junction of the accumulation region 16 and the trench bottom region 109 in the line f-f′. When the accumulation region 16 is not provided, a position of a PN junction between the trench bottom region 109 and the drift region 18 may be the position of the upper end m4 or the upper end m5.

A position of the lower end m6 may be a position of a PN junction of the trench bottom region 109 and the drift region 18 in the line f-f′. A position of the lower end m7 may be a position of the PN junction of the trench bottom region 109 and the drift region 18 in the line g-g′. An integrated value of the doping concentration of the trench bottom region 109 in the line g-g′ may be more than an integrated value of the doping concentration of the trench bottom region 109 in the line f-f′. In addition, when the bulk dopant is antimony, a doping concentration Dd of the drift region 18 may be 95% or more and 100% or less of an antimony chemical concentration.

FIG. 9B is a diagram illustrating another example of the first modification of the mesa portion 60. The mesa portion 60 of the present example includes the drift region 18 between the accumulation region 16 and the trench bottom region 109. In other words, the accumulation region 16 and the trench bottom region 109 are not in contact with each other. Other points are similar to those of the modification illustrated in FIG. 8.

FIG. 9C is a diagram illustrating another example of the doping concentration distribution in the depth direction of the mesa portion 60. FIG. 9C illustrates doping concentrations along the line f-f′ and the line g-g′ in FIG. 9B. The present example is different from the example illustrated in FIG. 9A in that a high-concentration portion of the accumulation region 16 does not reach the trench bottom region 109, and the trench bottom region 109 forms a PN junction with the drift region 18. That is, such a distribution can be formed by performing shallow ion implantation for forming the accumulation region 16 or not performing deep diffusion of the dopant. A position where the doping concentration becomes the doping concentration Dd of the bulk donor may exist between the accumulation region 16 and the trench bottom region 109. Also in such a case, a positional relationship of each junction described with reference to FIG. 9A is established.

FIG. 9D is a diagram illustrating another example of the first modification of the mesa portion 60. The mesa portion 60 of the present example does not include the accumulation region 16. In FIG. 8, the drift region 18 is provided in a region where the accumulation region 16 is provided. Other points are similar to those of the modification illustrated in FIG. 8.

FIG. 9E is a diagram illustrating another example of the doping concentration distribution in the depth direction of the mesa portion 60. The present example is different from the examples illustrated in FIGS. 9A and 9C in that the accumulation region 16 does not exist, and the base region 14 and the trench bottom region 109 form a PN junction with the drift region 18. That is, such a distribution can be formed by not performing ion implantation for forming the accumulation region 16. Also in such a case, a positional relationship of each junction described with reference to FIGS. 9A and 9C is established. Note that even when the trench bottom region 109 is not provided, a relationship in junction position between the base region 14 and the drift region 18 may be as in the present example.

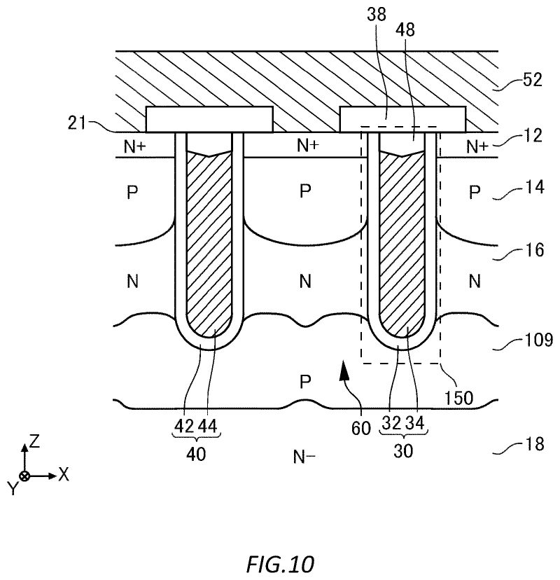

FIG. 10 is a diagram illustrating a second modification of the mesa portion 60. The mesa portion 60 of the present example includes the trench bottom region 109 in addition to the emitter region 12, the base region 14, and the accumulation region 16. The bulk dopant of the present example is phosphorus. As described above, under the annealing condition of the general IGBT, phosphorus is easily incorporated into the gate dielectric film 42, and the phosphorus concentration in the part in contact with the gate dielectric film 42 increases. Therefore, the dopant of the base region 14 and the dopant of the trench bottom region 109 less easily diffuse in the vicinity of the gate dielectric film 42. As a result, in the base region 14 of the present example, the lower end at the position in contact with the gate dielectric film 42 is arranged at a shallower position than the lower end at the center of the mesa portion 60. In addition, in the trench bottom region 109 of the present example, the upper end decreases toward the gate dielectric film 42. In other words, the upper end is in contact with the gate dielectric film 42 on a curved part that is convex upward. Therefore, the area of the accumulation region 16 of the N type in contact with the gate dielectric film 42 increases. As a result, the gate-collector capacitance increases, and as compared with the first modification illustrated in FIG. 8, the turn-on characteristic is deteriorated or the above-described effect is not sufficient.

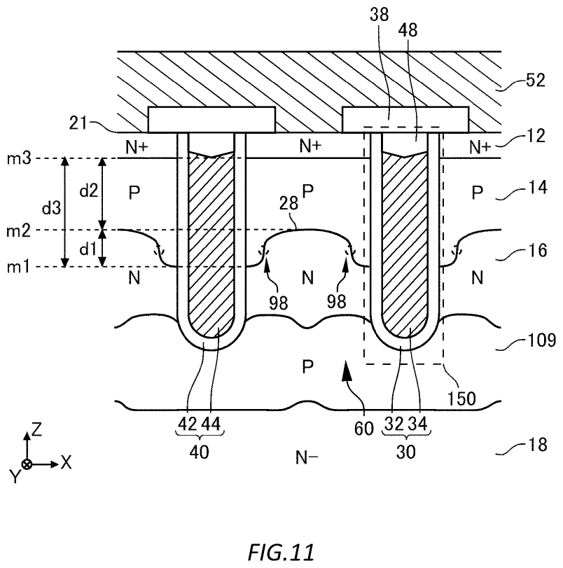

FIG. 11 is a diagram illustrating a third modification of the mesa portion 60. The lower end of the base region 14 of the present example has the shape illustrated in FIG. 4. The upper end of the trench bottom region 109 of the present example has the shape illustrated in FIG. 10. That is, although the bulk dopant of the present example is phosphorus, the first end portion m1 of the base region 14 is deepened by adjusting the ion implantation of the base region 14. Also in a case of the present example, the area of the accumulation region 16 of the N type in contact with the gate dielectric film 42 decreases. Therefore, the gate-collector capacitance can be reduced, and as compared with the second modification illustrated in FIG. 10, the turn-on characteristic can be improved or the above-described effect can be obtained.

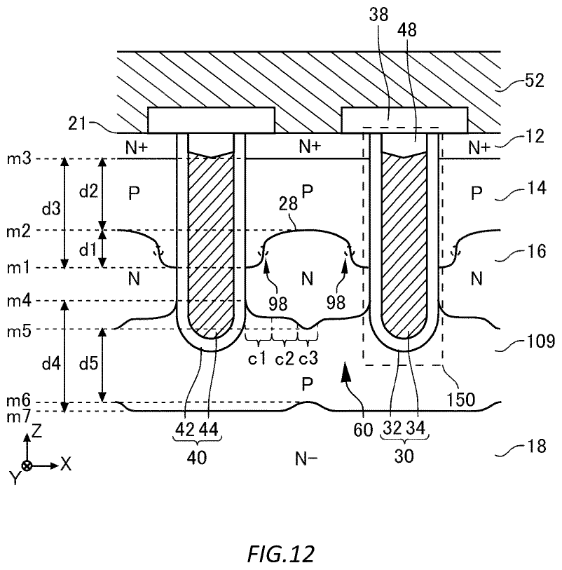

FIG. 12 is a diagram illustrating a fourth modification of the mesa portion 60. The lower end of the base region 14 of the present example has the shape illustrated in FIG. 4. The upper end of the trench bottom region 109 of the present example has the shape illustrated in FIG. 8. That is, the bulk dopant of the present example is antimony, and the first end portion m1 of the base region 14 is deepened by adjusting the ion implantation of the base region 14. In a case of the present example, the area of the accumulation region 16 of the N type in contact with the gate dielectric film 42 further decreases. Therefore, the gate-collector capacitance can be reduced, and as compared with the second modification illustrated in FIG. 10, the turn-on characteristic can be improved or the above-described effect can be obtained.

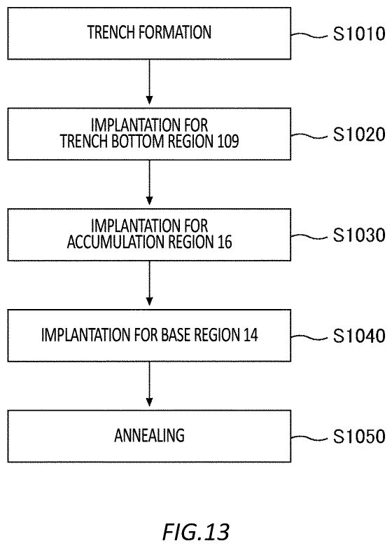

FIG. 13 illustrates an example of a manufacturing step of the semiconductor device 100. FIG. 13 illustrates a part of the manufacturing step. The manufacturing step of the present example includes a trench formation step S1010, an implantation step S1020 for the trench bottom region 109, an implantation step S1030 for the accumulation region 16, an implantation step S1040 for the base region 14 and an annealing step S1050.

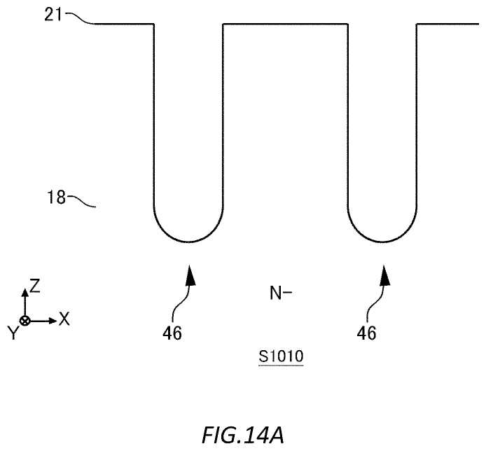

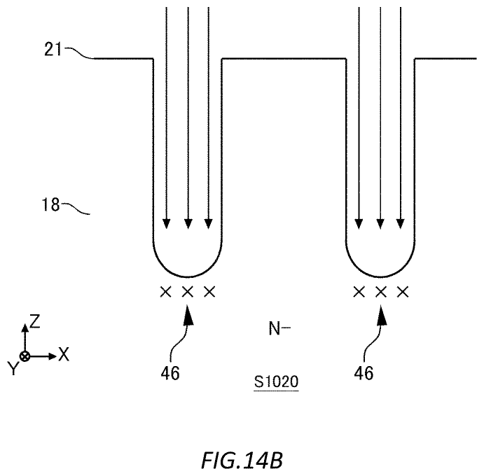

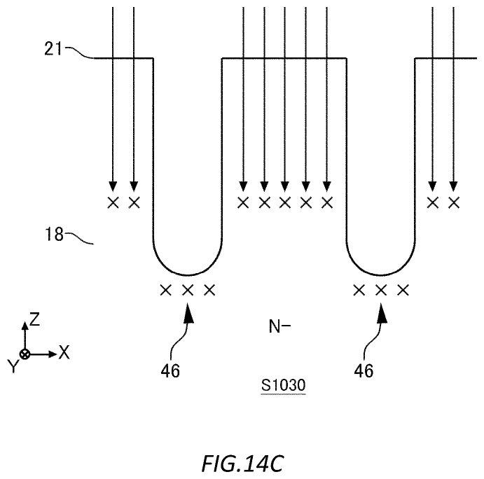

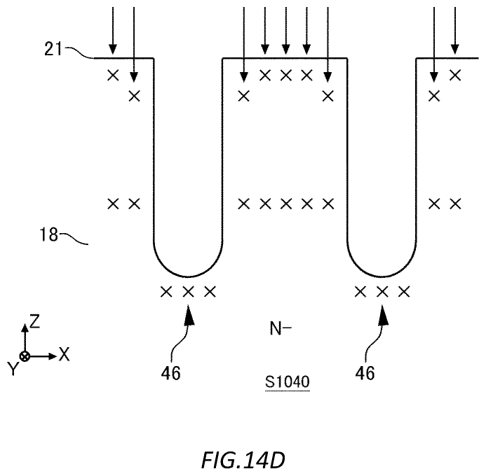

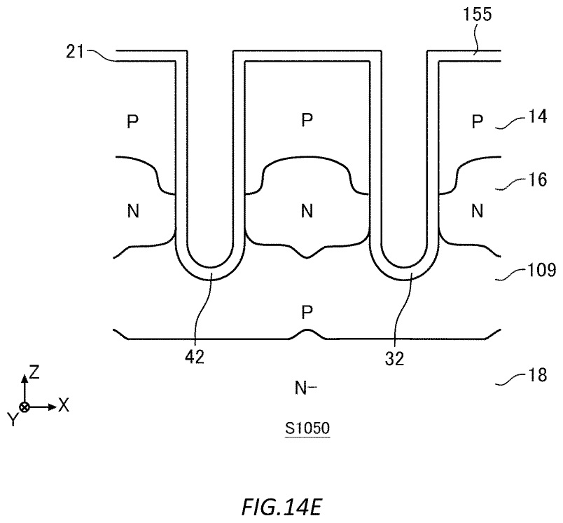

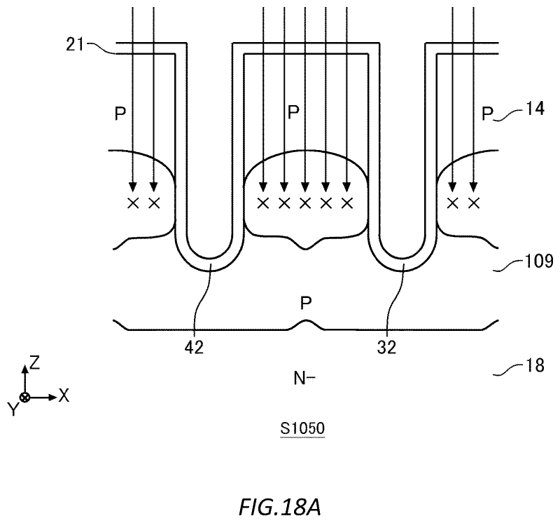

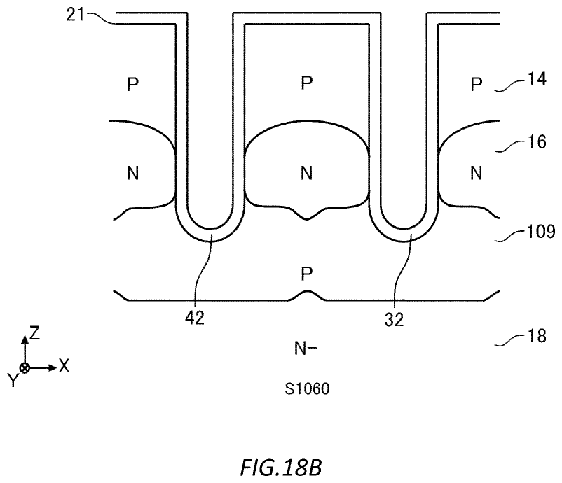

FIG. 14A is a diagram for explaining the trench formation step S1010. In the trench formation step S1010, a mask of a predetermined pattern is provided on the upper surface 21 of the semiconductor substrate 10, and the semiconductor substrate 10 is etched to form a trench 46. The bulk dopant of the semiconductor substrate 10 of the present example is antimony. Hereinafter, up to an example of FIG. 18B, the bulk dopant is antimony unless otherwise specified.

FIG. 14B is a diagram for explaining the implantation step S1020 for the trench bottom region 109. In the implantation step S1020 for the trench bottom region 109, the dopant of the trench bottom region 109 is implanted into the semiconductor substrate 10 from a bottom portion of the trench 46. The dopant of the present example is boron.

FIG. 14C is a diagram for explaining the implantation step S1030 for the accumulation region 16. In the implantation step S1030 for the accumulation region 16, the dopant of the accumulation region 16 is implanted to a predetermined depth from the upper surface 21 of the semiconductor substrate 10. The dopant of the present example is phosphorus.

FIG. 14D is a diagram for explaining the implantation step S1040 for the base region 14. In the implantation step S1040 for the base region 14, the dopant of the base region 14 is implanted to a predetermined depth from the upper surface 21 of the semiconductor substrate 10. In the implantation step S1040 for the base region 14 of the present example, a depth position of the dopant implanted in a vicinity of the trench 46 is made deeper than a depth position of the dopant implanted in the center of the mesa portion. In another example, a dose amount of the dopant implanted in the vicinity of the trench 46 may be larger than a dose amount of the dopant implanted in the center of the mesa portion. In addition, both the depth position and the dose amount may be changed. In addition, a step of implanting the dopant in the center of the mesa portion and a step of implanting the dopant in the vicinity of the trench 46, including patterning of a resist, may be performed separately or simultaneously. The dopant of the present example is boron.

FIG. 14E is a diagram for explaining the annealing step S1050. In the annealing step S1050, the gate dielectric film 42 is formed, and the base region 14, the accumulation region 16, and the trench bottom region 109 are formed. In the present example, the semiconductor substrate 10 is heated and oxidized to form an oxide film 155 on the upper surface 21 and an inner surface of the trench 46. The oxide film 155 in the trench 46 becomes the gate dielectric film 42 or the dummy dielectric film 32. At this time, antimony (bulk dopant) of the semiconductor substrate 10 located in its periphery is also incorporated into the gate dielectric film 42.

An annealing temperature is, as an example, 1100° C. or lower or 1050° C. or lower, and 900° C. or higher or 950° C. or higher. In this case, antimony is less easily incorporated into the gate dielectric film 42 than phosphorus. Therefore, a concentration of antimony in the vicinity of the gate dielectric film 42 is lower than that at the center of the mesa portion 60 or the like.

On the other hand, by annealing the semiconductor substrate 10, the dopant is diffused and activated to form the base region 14, the accumulation region 16, and the trench bottom region 109. Since the concentration of antimony in the vicinity of the gate dielectric film 42 is low, the dopant of the trench bottom region 109 easily diffuses in the vicinity of the gate dielectric film 42. As a result, the upper end of the trench bottom region 109 approaches the upper surface 21 side as approaching the gate dielectric film 42.

In the base region 14, the depth position of the dopant implanted in the vicinity of the trench 46 is made deep, so that the lower end is formed deep in the vicinity of the gate dielectric film 42. In addition, the lower end of the base region 14 may approach the lower surface 23 side in the vicinity of the gate dielectric film 42 due to influence of the antimony described above. The shapes of the lower end of the base region 14 and the trench bottom region 109 illustrated in FIG. 14E may be similar to those in FIG. 12.

In another case, the shapes of the lower end of the base region 14 and the trench bottom region 109 illustrated in FIG. 11 may be formed. For example, when phosphorus is used as the dopant of the accumulation region 16 to form a high concentration, a shape of a boundary with the trench bottom region 109 may be as illustrated in FIG. 11. In addition, the bulk dopant of the semiconductor substrate 10 is not limited to antimony. For example, the bulk dopant may be phosphorus. In the base region 14, the depth position of the dopant implanted in the vicinity of the trench 46 is made deep, so that the lower end is formed deep in the vicinity of the gate dielectric film 42. Also at this time, the shapes of the lower end of the base region 14 and the trench bottom region 109 illustrated in FIG. 11 may be formed.

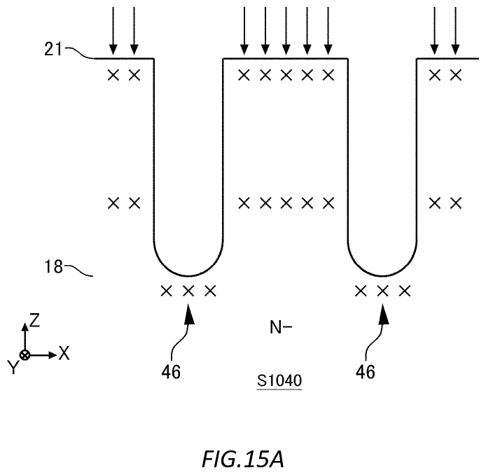

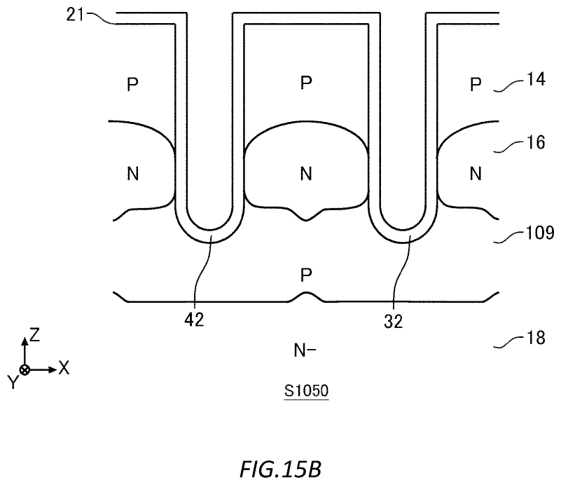

FIG. 15A is a diagram for explaining another example of the implantation step S1040 for the base region 14. In the implantation step S1040 for the base region 14 of the present example, the dopant is uniformly implanted in the array direction of the mesa portion 60.

FIG. 15B is a diagram for explaining another example of the annealing step S1050. In the annealing step S1050 of the present example, the semiconductor substrate 10 implanted uniformly with the dopant of the base region 14 in FIG. 15A is annealed. The bulk dopant of the present example is also antimony. Therefore, the dopant of the base region 14 easily diffuses in the vicinity of the gate dielectric film 42. As a result, the upper end of the base region 14 approaches the lower surface 23 side as approaching the gate dielectric film 42. The shapes of the lower end of the base region 14 and the trench bottom region 109 illustrated in FIG. 15B may be similar to those in FIG. 8. In another case, for example, depending on the concentration, element, or position of the accumulation region 16, any of the lower end of the base region 14 or the trench bottom region 109 may be formed in the shape illustrated in FIG. 10.

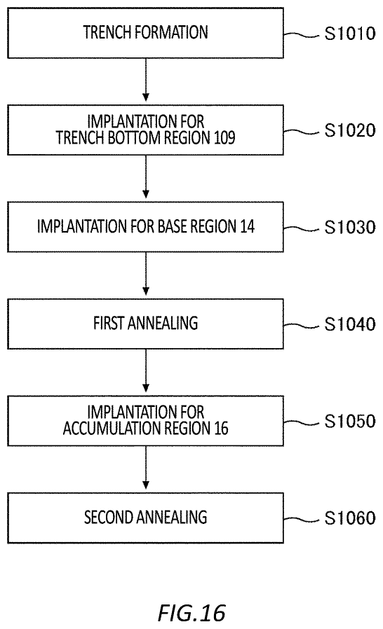

FIG. 16 is a diagram illustrating another example of the manufacturing step of the semiconductor device 100. The manufacturing step of the present example is different from the manufacturing step illustrated in FIG. 13 in that the implantation step S1050 for the accumulation region 16 and a second annealing step S1060 are performed after the first annealing step S1040. The first annealing step S1040 of the present example corresponds to the annealing step S1050 in FIG. 13. That is, the manufacturing step of the present example is similar to that in FIG. 13 except that the dopant of the accumulation region 16 is not implanted and formed until the first annealing step S1040.

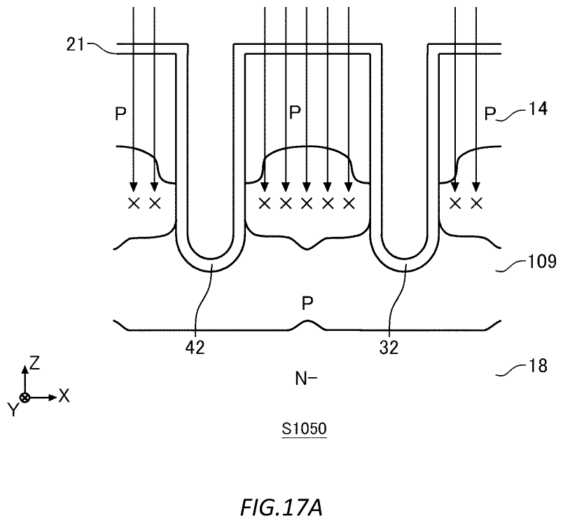

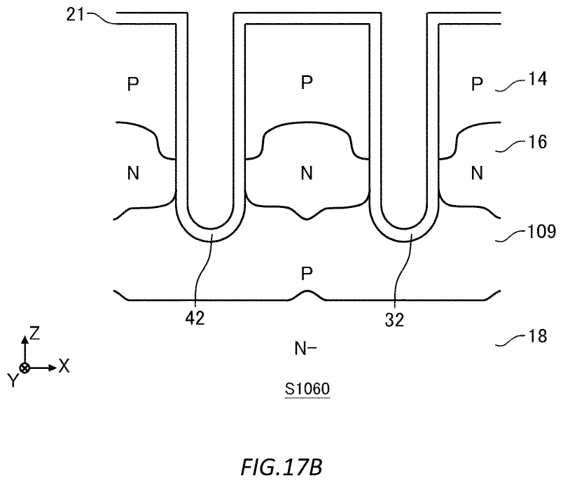

FIG. 17A is a diagram for explaining the implantation step S1050 for the accumulation region 16 in FIG. 16. The base region 14 and the trench bottom region 109 are formed by the implantation step S1050 for the accumulation region 16. The shapes of the base region 14 and the trench bottom region 109 of the present example are the shapes illustrated in FIG. 12. In the implantation step S1050 for the accumulation region 16, the dopant of the accumulation region 16 is implanted to a depth between the base region 14 and the trench bottom region 109 from the upper surface 21 of the semiconductor substrate 10. Note that the oxide film on the upper surface 21 of the mesa portion 60 may be removed before the ion implantation.

FIG. 17B is a diagram for explaining the second annealing step S1060 in FIG. 16. In the second annealing step S1060, the dopant of the accumulation region 16 is diffused and activated to form the accumulation region 16. An annealing temperature in the second annealing step S1060 is, as an example, 1000° C. or lower. The annealing temperature in the second annealing step S1060 may be lower than the annealing temperature in the first annealing step S1040. The semiconductor device 100 of the example can also be manufactured by such a method. The shapes of the lower end of the base region 14 and the trench bottom region 109 illustrated in FIG. 17B may be similar to those in FIG. 12. In addition, the shapes may be similar to those in FIG. 11.

FIG. 18A is a diagram for explaining another example of the implantation step S1050 for the accumulation region 16 in FIG. 16. The shapes of the base region 14 and the trench bottom region 109 of the present example are the shapes illustrated in FIG. 8. Other points are similar to those of the example illustrated in FIG. 17A.

FIG. 18B is a diagram for explaining another example of the second annealing step S1060 in FIG. 16. In the second annealing step S1060 of the present example, the dopant of the accumulation region 16 is diffused and activated in the semiconductor substrate 10 of FIG. 18A to form the accumulation region 16. The semiconductor device 100 of the example can also be manufactured by such a method. The shapes of the lower end of the base region 14 and the trench bottom region 109 illustrated in FIG. 18B may be similar to those in FIG. 8. In another case, any of the lower end of the base region 14 or the trench bottom region 109 may be formed in the shape illustrated in FIG. 10.

In each example of the manufacturing method, an adjacent trench portion 150 side (a dummy dielectric film 32 side in each example) may also be formed in a shape similar to that of a gate dielectric film 42 side. That is, the shapes of the base region 14 and the trench bottom region 109 may be line-symmetric with respect to a line that extends at the center of the mesa portion 60 in the depth direction. Note that in all the examples, the trench bottom region 109 may not be formed. In addition, the accumulation region 16 may not be formed.

In each example of the manufacturing method, it is not essential that the formation of the gate dielectric film 42 and the diffusion of the dopant are performed in a same annealing step. The gate dielectric film 42 may be formed first, and the dopant may be diffused in a later step. In addition, when adjusting the ion implantation of the dopant of the base region 14 illustrated in FIG. 14D or the like, the gate dielectric film 42 may be formed after the annealing step of the base region 14. For example, after the base region 14 is formed, the trench 46 may be formed, and the gate dielectric film 42 may be formed. Also during the ion implantation of each dopant, an inside of the trench 46 or the upper surface 21 may be covered with the oxide film 155, and the oxide film 155 at this time may, as it is, serve as the gate dielectric film 42 or may be removed once in a middle of manufacturing. Before or simultaneously with diffusion of each dopant, the gate conductive portion 44 or the interlayer dielectric films 38 and 48 may be formed in the trench 46.

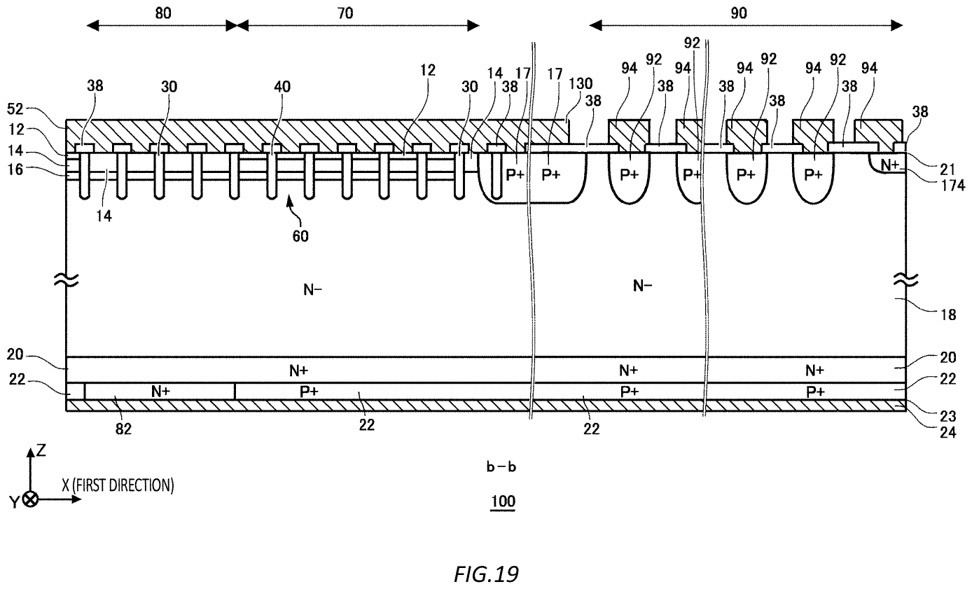

FIG. 19 is a view illustrating an example of a cross section b-b in FIG. 1. The cross section b-b is an XZ plane passing through the edge termination structure portion 90, the transistor portion 70, and the diode portion 80. A structure of the transistor portion 70 and the diode portion 80 are the same as that of the transistor portion 70 and the diode portion 80 described in FIGS. 2 and 3. In FIG. 19, a structure of the gate trench portion 40, the dummy trench portion 30, and the mesa portion 60 is illustrated in a simplified manner.

In the semiconductor substrate 10, the well region 17 is provided between the edge termination structure portion 90 and the transistor portion 70. The well region 17 is a region of the P+ type in contact with the upper surface 21 of the semiconductor substrate 10. The well region 17 may be provided up to a position deeper than the lower ends of the gate trench portion 40 and the dummy trench portion 30. A part of the gate trench portion 40 and a part of the dummy trench portion 30 may be arranged inside the well region 17.

The interlayer dielectric film 38 covering the well region 17 may be provided on the upper surface 21 of the semiconductor substrate 10. Above the interlayer dielectric film 38, electrodes and wirings such as the emitter electrode 52 and the outer circumferential gate runner 130 are provided. The emitter electrode 52 is provided to extend from above the active portion 160 to above the well region 17. The emitter electrode 52 may be connected to the well region 17 via a contact hole provided in the interlayer dielectric film 38.

The outer circumferential gate runner 130 is arranged between the emitter electrode 52 and the edge termination structure portion 90. Although the emitter electrode 52 and the outer circumferential gate runner 130 are arranged separately from each other, a gap between the emitter electrode 52 and the outer circumferential gate runner 130 is omitted in FIG. 4. The outer circumferential gate runner 130 is electrically insulated from the well region 17 by the interlayer dielectric film 38.

The edge termination structure portion 90 is provided between the active portion 160 and an end portion of the semiconductor substrate 10 at the upper surface 21 of the semiconductor substrate 10. The end portion may be any of the end sides 162 of the semiconductor substrate 10 in FIG. 1. In the present specification, a direction from the active portion 160 toward the end portion of the semiconductor substrate 10 may be referred to as a first direction. In FIG. 19, a positive direction of the X axis is the first direction. However, in another cross section, a negative direction of the X axis, a positive direction of the Y axis, or a negative direction of the Y axis may be the first direction.

The edge termination structure portion 90 is provided with a plurality of guard rings 92, a plurality of field plates 94, a channel stopper 174, and the interlayer dielectric film 38. In the edge termination structure portion 90, the drift region 18 of the N− type is provided inside the semiconductor substrate 10. In addition, the collector region 22 of the P+ type may be provided in a region in contact with the lower surface 23. The buffer region 20 of the N+ type may be provided between the collector region 22 and the drift region 18.

The interlayer dielectric film 38 is provided on the upper surface 21 of the semiconductor substrate 10. The interlayer dielectric film 38 may be made of a same material as that of the interlayer dielectric film 38 of the active portion 160, and may be an oxide film formed by oxidizing the semiconductor substrate 10 or a nitride film formed by nitriding. The interlayer dielectric film 38 of the present example covers a part of the adjacent guard rings 92 and the drift region 18 between the guard rings 92.

Each guard ring 92 may be provided so as to enclose the active portion 160 at the upper surface 21. The plurality of guard rings 92 may have a function of spreading the depletion layer generated in the active portion 160 to an outside of the semiconductor substrate 10. With this configuration, the electric field strength inside the semiconductor substrate 10 can be prevented, and the breakdown voltage of the semiconductor device 100 can be improved.

The guard ring 92 of the present example is a semiconductor region of the P+ type formed by ion implantation in a vicinity of the upper surface 21. A depth of a bottom portion of the guard ring 92 may be deeper than depths of the bottom portions of the gate trench portion 40 and the dummy trench portion 30. The depth of the bottom portion of the guard ring 92 may be the same as or different from a depth of a bottom portion of the well region 17.

The guard ring 92 may be exposed on the upper surface 21 of the semiconductor substrate 10. At least a part of the guard ring 92 may be in contact with the interlayer dielectric film 38 at the upper surface 21 of the semiconductor substrate 10. An upper surface of the guard ring 92 of the present example is covered with the interlayer dielectric film 38. A shape of the guard ring 92 will be described later.

The field plate 94 is formed of a metal such as aluminum or a conductive material such as polysilicon. The field plate 94 may be formed of an aluminum-silicon alloy, for example, a metal alloy such as AlSi or AlSiCu. The field plate 94 may be formed of a same material as the outer circumferential gate runner 130 or the emitter electrode 52. The field plate 94 is provided on the interlayer dielectric film 38. The field plate 94 of the present example is connected to the guard ring 92 through a through hole provided in the interlayer dielectric film 38.

The channel stopper 174 is provided to be exposed on the upper surface 21 and the side wall in a vicinity of the end side 162 of the semiconductor substrate 10. The channel stopper 174 is a region of the N+ type or the P+ type having a doping concentration higher than that of the drift region 18. The channel stopper 174 has a function of terminating the depletion layer generated in the active portion 160 in the vicinity of the end side 162 of the semiconductor substrate 10.

In FIG. 19, the interlayer dielectric films 38 of the transistor portion 70, the diode portion 80, and the edge termination structure portion 90 are drawn to have a same thickness, but a thickness may differ, and a formation process and a composition may also differ. Note that although at least a part of the field plate 94, the outer circumferential gate runner 130, and the emitter electrode 52 is covered with a protective film such as a polyimide or nitride film, the protective film is omitted in the drawings of the present specification.

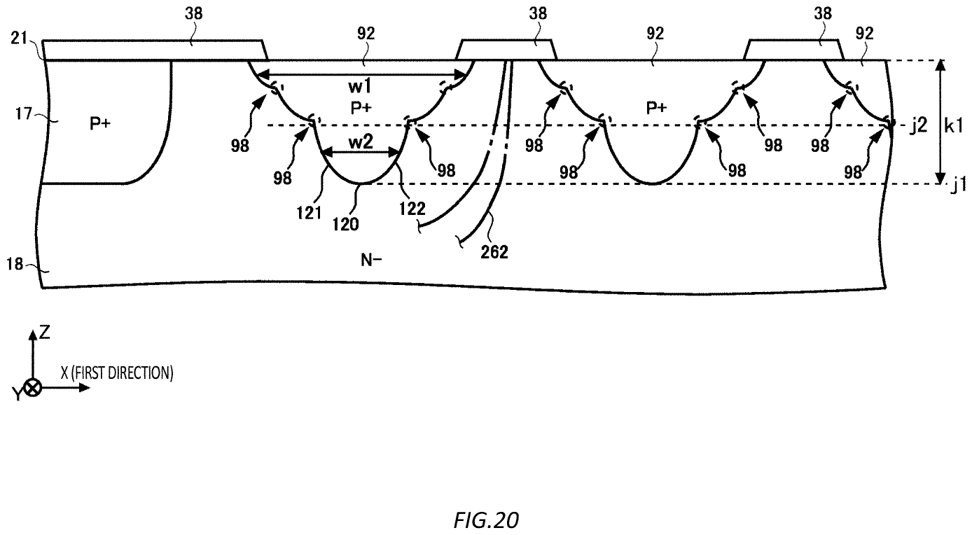

FIG. 20 is an enlarged view of the semiconductor substrate 10 in a vicinity of the well region 17 and the guard ring 92 in FIG. 19. In FIG. 20, the field plate 94 and the lower surface 23 side of the semiconductor substrate 10 are omitted.

A cross section parallel to both the first direction and the depth direction of the semiconductor substrate 10 is defined as a first cross section. The cross section b-b, that is, the cross sections of FIGS. 19 and 20 is an example of the first cross section. The guard ring 92 has at least one side surface in the first cross section. The guard ring 92 of the present example has a lower end 120, a first side surface 121, and a second side surface 122 in the first cross section. The first side surface 121 is a side surface on the active portion 160 side with respect to the lower end 120, and the second side surface 122 is a side surface on an end portion side of the semiconductor substrate 10 with respect to the lower end 120. Since FIG. 20 is a cross section, the side surface is indicated by a curve. The lower end 120 may be at a deepest position of the guard ring 92 (a position away from the upper surface 21).

The side surface of the guard ring 92 may have one or more inflection points 98 in the first cross section. An inflection point is a point at which, when the curve is regarded as the function of z=f(x) in the XZ coordinate system, a sign of a second derivative of the function changes. Each of the first side surface 121 and the second side surface 122 may have one or more inflection points 98. In the guard ring 92 of the present example, each of the first side surface 121 and the second side surface 122 has two inflection points 98. The side surface of the guard ring 92 may be a boundary surface between the guard ring 92 and the drift region 18.

In the guard ring 92, a width in the first direction of a part between the inflection point 98 closest to the interlayer dielectric film 38 and the interlayer dielectric film 38 is defined as w1. In addition, a width of a part between the inflection point 98 and the lower end 120 of the guard ring 92 is defined as w2. When there is a plurality of inflection points 98, the inflection point 98 defining the width w2 may be any inflection point. The width w1 may be wider than the width w2.

A region of the N type may be provided between the guard rings 92. The drift region 18 is provided between the guard rings 92 of the present example. When the width w1 is larger than the width w2, a difference between a width of the drift region 18 between the guard rings 92 at the upper surface 21 and a width of the drift region 18 at a depth position of the lower end 120 of the guard ring 92 increases. As a result, an electric field distribution in a vicinity of the lower end 120 of the guard ring 92 is further relaxed. FIG. 20 schematically illustrates equipotential lines 262. The guard ring 92 having such a shape can be formed by performing ion implantation with different implantation depths or different dose amounts a plurality of times.

Since the guard ring 92 has the inflection point 98, the width w1 can be easily increased. The width w1 may be 1.2 times or more, 1.5 times or more, or 2 times or more the width w2. The width w1 may be a width of the guard ring 92 at a position of the upper surface 21. The width w2 may be a width of the guard ring 92 on the lower surface 23 side with respect to the center in the depth direction of the guard ring 92. In FIG. 20, a position in the depth direction of the lower end 120 of the guard ring 92 is defined as j1, and a center position in the depth direction of the guard ring 92 is defined as j2.

At least one inflection point 98 may be arranged on the upper surface 21 side of the semiconductor substrate 10 with respect to the center position j2 in the depth direction of the guard ring 92. Two or more inflection points 98 may be arranged on the upper surface 21 side with respect to the center position j2, and three or more inflection points 98 may be arranged on the upper surface 21 side with respect to the center position j2. In the present example, all the inflection points 98 are arranged on the upper surface 21 side with respect to the center position j2.

A distance from the upper surface 21 to the lower end 120 of the guard ring 92 is defined as k1. The inflection point 98 may be located within ⅓, or ¼, of the distance k1 from the upper surface 21 in the depth direction. Two or more inflection points 98 may be located within ⅓, or ¼, of the distance k1 from the upper surface 21 in the depth direction. Three or more inflection points 98 may be located within ⅓, or ¼, of the distance k1 from the upper surface 21 in the depth direction. A relationship between these inflection points 98 may be established by each of the plurality of guard rings 92. In addition, the shape of the guard ring 92 may be line-symmetric about a line parallel to the depth direction passing through the lower end 120.

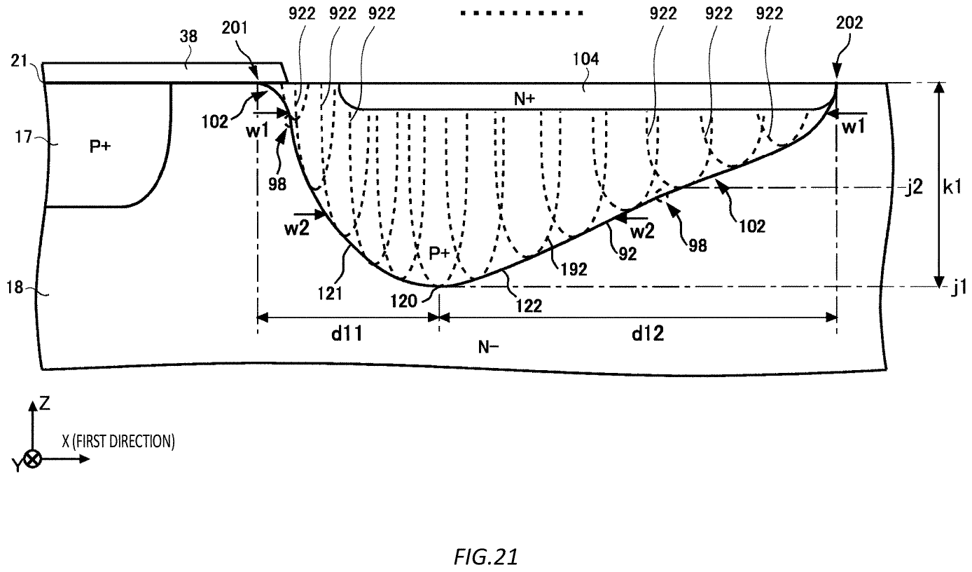

FIG. 21 is a view illustrating another example of the guard ring 92. The guard ring 92 of the present example is formed deeper than the guard ring 92 illustrated in FIG. 20. The guard ring 92 may be formed deeper than the well region 17. In addition, a width in the first direction is also wider than that of the guard ring 92 illustrated in FIG. 20. The guard ring 92 of the present example also has the inflection point 98. In addition, also in the present example, a relationship between the width w1 and the width w2 described above is established.

In the guard ring 92 of the present example, the first side surface 121 and the second side surface 122 are asymmetrically provided. The second side surface 122 of the present example is longer in the first direction than the first side surface 121. Therefore, the inflection point 98 of the first side surface 121 and the inflection point of the second side surface 122 are provided at different depth positions.

An end portion of the guard ring 92 on the active portion 160 side is defined as a first end portion 201. In the present example, an end portion of the guard ring 92 on a negative side in the X axis direction is defined as the first end portion 201. An end portion of the guard ring 92 on an end side 162 side of the semiconductor substrate 10 is defined as a second end portion 202. In other words, the second end portion is an outer peripheral side end portion of the semiconductor substrate 10 in the guard ring 92. In the present example, an end portion of the guard ring 92 on a positive side in the X axis direction is the second end portion 202.

A distance between the position of the lower end 120 and the first end portion 201 in the top view is defined as d11. A distance between the position of the lower end 120 and the second end portion 202 in the top view is defined as d12. In FIG. 21, the distance d11 and the distance d12 are distances in the X axis direction. The distance d12 of the present example is larger than the distance d11. The distance d12 may be 1.2 times or more, 1.5 times or more, 2 times or more, or 5 times or more the distance d11. The distance d12 may be 10 times or less the distance d11.

In the guard ring 92 of the present example, as an example, a plurality of individual guard rings 922 formed by performing ion implantation with different implantation depths and different dose amounts a plurality of times are overlapped in the X axis direction to form an aggregate, and an envelope thereof is one guard ring 92. In FIG. 21, the plurality of individual guard rings 922 formed by respective ion implantations are indicated by dotted lines. The guard ring 92 illustrated in FIG. 21 has a shape of an envelope in which these individual guard rings 922 overlap (Variable Lateral Doping (VLD)). A similar shape may be formed by varying an implantation depth by a single ion implantation using an inclined resist or by diffusing and connecting regions formed in a single ion implantation by varying a density of openings of the resist. A high-concentration region 104 of the N+ type may be provided between a part of the guard ring 92 and the upper surface 21. This makes it possible to ensure resistance to a breakdown voltage fluctuation from external charges.

The guard ring 92 may have an edge curved surface 102. A side surface of the guard ring 92 of the present example has an edge curve between the lower end 120 and the second end portion 202. The side surface of the guard ring 92 of the present example has an edge curve between the lower end 120 and the first end portion 201. The edge curved surface 102 will be described later.

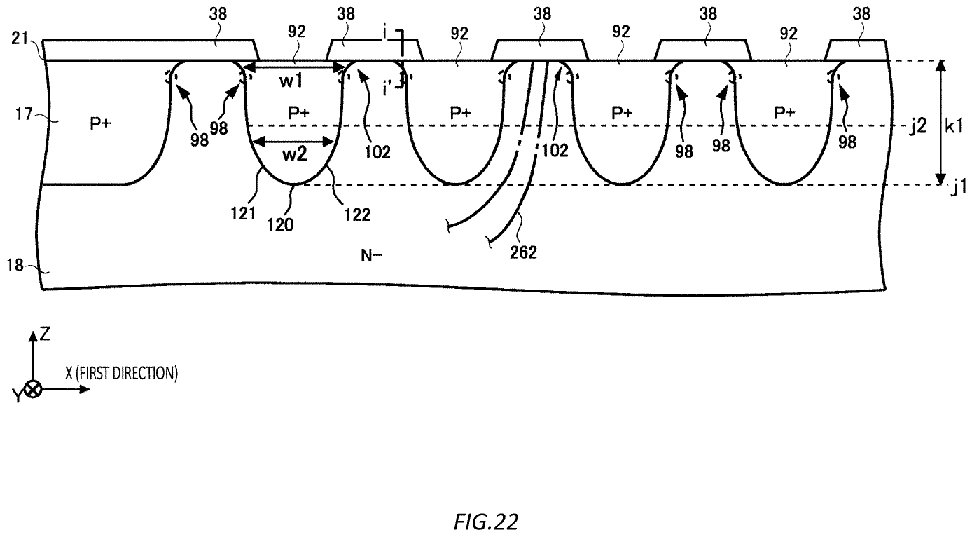

FIG. 22 is a view illustrating another example of the guard ring 92. The side surface of the guard ring 92 of the present example also has the inflection point 98. The side surface of the guard ring 92 of the present example has an edge curved surface 102. The edge curved surface 102 is a curved surface that is convex toward the upper surface 21 of the semiconductor substrate 10 in a direction of the interlayer dielectric film 38. The curved surface being convex upward may mean that a line segment connecting two points on a curve existing on the curved surface is always below the curve. In this case, a point at which a first derivative is zero is not necessarily included between the two points. In the first cross section, the edge curved surface 102 is represented as a curve on the edge curved surface 102. The edge curved surface 102 of the present example is located between the upper surface 21 and the inflection point 98.

A part, between the inflection points 98, of the side surface of the guard ring 92 of the present example is a curved surface that is convex downward. The curved surface being convex downward may mean that a line segment connecting two points on a curve existing on the curved surface is always above the curve. In this case, a point at which a first derivative is zero is not necessarily included between the two points.

The edge curved surface 102 of the guard ring 92 may be in contact with the interlayer dielectric film 38. In the first cross section of FIG. 22, the curve on the edge curved surface 102 is in contact with the interlayer dielectric film 38. In other words, the edge curved surface 102 may be exposed on the upper surface of the semiconductor substrate 10. The width w2 can be made larger than the width w1 due to the edge curved surface 102, and the electric field distribution in the vicinity of the lower end 120 of the guard ring 92 is further relaxed.

The position in the depth direction of the inflection point 98 of the present example may be the same as the position described in FIG. 20. In addition, both the first side surface 121 and the second side surface 122 may have the edge curved surfaces 102. A plurality of guard rings 92 may be provided with the edge curved surfaces 102. In addition, the side surface of the well region 17 may also have the inflection point 98 and the edge curved surface 102. In addition, the guard ring 92 of the present example may also be line-symmetric about a line parallel to the depth direction passing through the lower end 120.

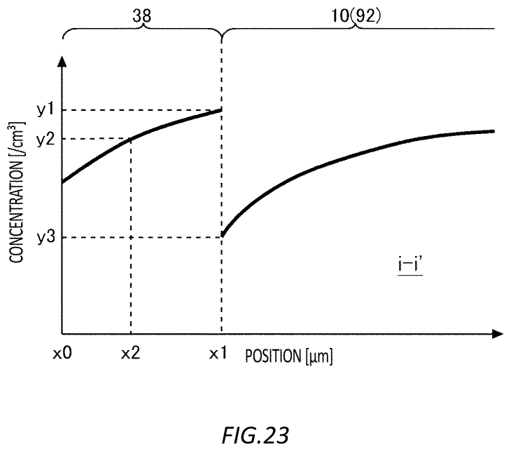

FIG. 23 is a diagram illustrating a chemical concentration distribution of the bulk dopant along a line i-i′ in FIG. 22. The line i-i′ is a line that extends to the guard ring 92 of the semiconductor substrate 10 across the interlayer dielectric film 38 in the depth direction. In FIG. 23, a horizontal axis represents a position in the depth direction, and a vertical axis represents a chemical concentration of the bulk dopant. The bulk dopant of the present example is antimony.

Incorporation of the bulk dopant into the gate dielectric film 42 described in the mesa portion 60 also occurs in the edge termination structure portion 90. That is, when the semiconductor substrate 10 is oxidized or nitrided to form the interlayer dielectric film 38, the bulk dopant around the interlayer dielectric film 38 is incorporated into the interlayer dielectric film 38. At that time, incorporation into the interlayer dielectric film 38 differs depending on a type of the bulk dopant and the annealing condition.

Under the annealing condition of the guard ring 92 of the general IGBT, when the bulk dopant is phosphorus, the bulk dopant is easily incorporated into the interlayer dielectric film 38, and a phosphorus concentration in a part in contact with the interlayer dielectric film 38 increases. On the other hand, when the bulk dopant is antimony, the bulk dopant is less easily incorporated into the gate dielectric film 42. As a result, the antimony concentration decreases in a vicinity of the interlayer dielectric film 38. Since the dopant of the guard ring 92 easily diffuses in a region where the antimony concentration decreases, the guard ring 92 having a shape of FIG. 22 is formed.

The semiconductor substrate 10 of the present example contains antimony as the bulk dopant. The antimony concentration may decrease as approaching the interlayer dielectric film 38. However, the guard ring 92 having the shape of FIG. 22 may be formed by adjusting the depth position, the dose amount, or the like when the dopant of the guard ring 92 is ion-implanted.

The interlayer dielectric film 38 may contain the bulk dopant. The interlayer dielectric film 38 of the present example contains antimony. The position x0 in FIG. 23 is an end portion of the interlayer dielectric film 38 on a side opposite to the upper surface 21. The first position x1 is a position where the interlayer dielectric film 38 and the upper surface 21 of the semiconductor substrate 10 are in contact with each other. The chemical concentration of the bulk dopant of the interlayer dielectric film 38 at the first position x1 is defined as y1. The second position x2 is a position in the interlayer dielectric film 38 farther from the upper surface 21 of the semiconductor substrate 10 than the first position x1. The second position x2 may be a center in the depth direction of the interlayer dielectric film 38 and may be equal to the position x0. The chemical concentration of the bulk dopant at the second position x2 is defined as y2.

The concentration y1 may be higher than the concentration y2. As described above, the interlayer dielectric film 38 allows incorporation of the bulk dopant from the semiconductor substrate 10, so that the chemical concentration of the bulk dopant at a position in contact with the semiconductor substrate 10 increases. The concentration y1 may be 1.2 times or more, 1.5 times or more, 2 times or more, 5 times or more, or 10 times or more the concentration y2. The concentration y1 may be a maximum value of the chemical concentration of the bulk dopant of the interlayer dielectric film 38. The chemical concentration of the bulk dopant of the interlayer dielectric film 38 may decrease as a distance from the upper surface 21 of the semiconductor substrate 10 increases.

The chemical concentration of the bulk dopant of the guard ring 92 at the first position x1 is defined as y3. The concentration y3 may be lower than the concentration y1. As described above, the bulk dopant around the interlayer dielectric film 38 is incorporated into the interlayer dielectric film 38, so that the concentration y3 decreases. The concentration y3 may be lower than the concentration y2. The concentration y3 may be lower than a minimum value of the chemical concentration of the bulk dopant of the interlayer dielectric film 38.

In the semiconductor substrate 10, the chemical concentration of the bulk dopant in the drift region 18 may be higher than the chemical concentration of the bulk dopant at a position in contact with the interlayer dielectric film 38. The drift region 18 may be the drift region 18 of the edge termination structure portion 90. As the chemical concentration of the bulk dopant in the drift region 18, an average value of the drift region 18 may be used. The position in contact with the interlayer dielectric film 38 may be a position (first position x1) at which the guard ring 92 is in contact with the gate dielectric film 42. In this case, the chemical concentration of the bulk dopant is defined as y3. A difference in the concentration may be 1.5 times or more, 2 times or more, 5 times or more, or 10 times or more.

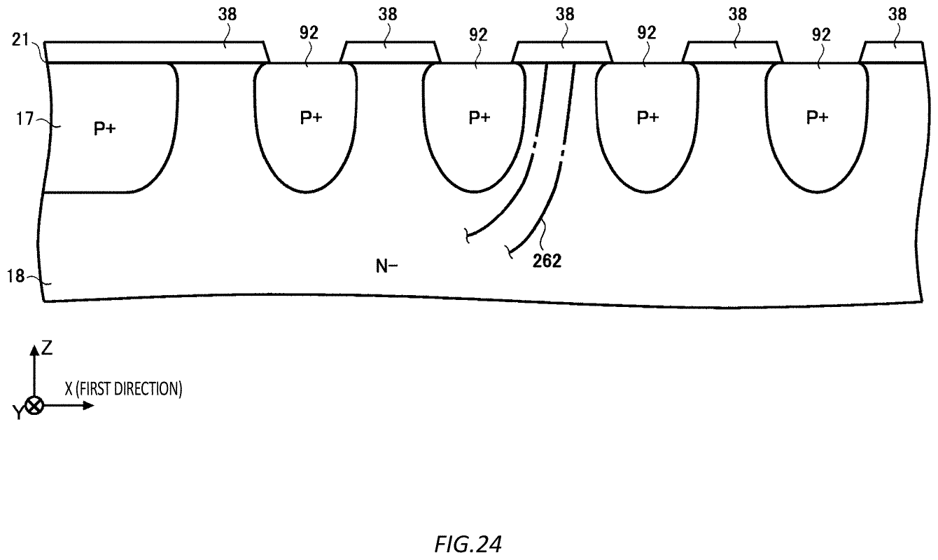

FIG. 24 is a view illustrating the guard ring 92 in a comparative example. The bulk dopant of the comparative example is phosphorus. As described above, under the annealing condition of the general IGBT, phosphorus of the bulk dopant is not incorporated into the interlayer dielectric film 38 at a same chemical concentration as the chemical concentration of the bulk dopant of the semiconductor substrate 10, and the phosphorus concentration in the part in contact with the interlayer dielectric film 38 increases. Therefore, in the vicinity of the interlayer dielectric film 38, a junction with the guard ring 92 is formed on a side close to the guard ring 92. As a result, a width of the guard ring 92 of the comparative example at the upper surface 21 is narrowed. Therefore, the difference between the width of the drift region 18 between the guard rings 92 at the upper surface 21 and the width of the drift region 18 at the depth position of the lower end 120 of the guard ring 92 is smaller than that in the example. As a result, the electric field distribution in the vicinity of the lower end 120 of the guard ring 92 is less likely to be relaxed.

Note that the examples of the active portion 160 described in FIGS. 4 to 12 and the examples of the guard ring 92 of the edge termination structure portion 90 described in FIGS. 20 to 23 may be arbitrarily combined. That is, the semiconductor device 100 may include any of the active portions 160 described in FIGS. 4 to 12 and any of the edge termination structure portions 90 described in FIGS. 20 to 23. With this configuration, it is possible to relax the electric field distribution while improving the turn-on characteristic.

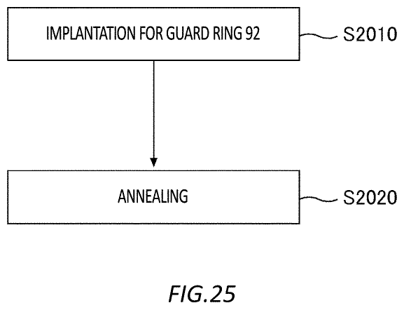

FIG. 25 is a diagram illustrating an example of a manufacturing step of the edge termination structure portion 90. FIG. 25 illustrates a part of the manufacturing step. The manufacturing step of the present example includes an implantation step S2010 for the guard ring 92 and an annealing step S2020.

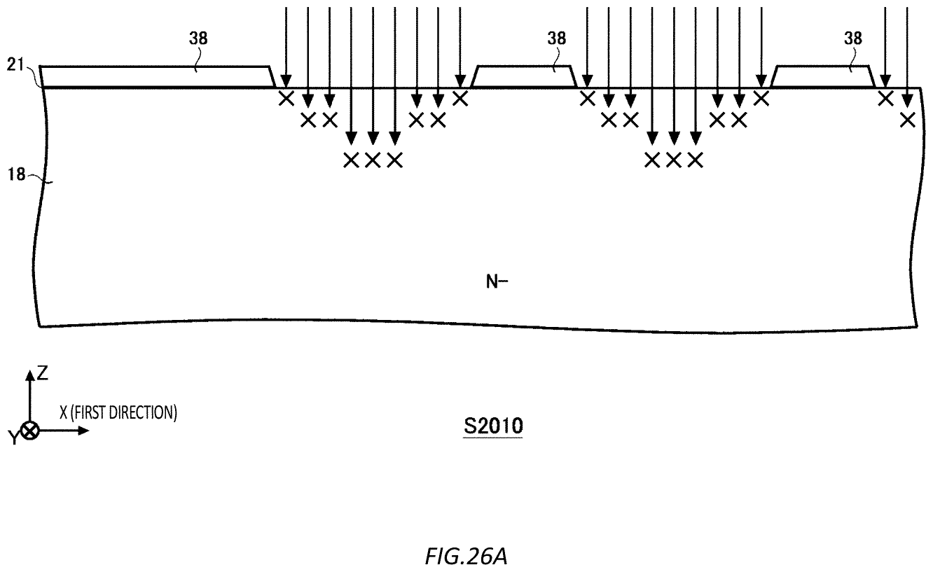

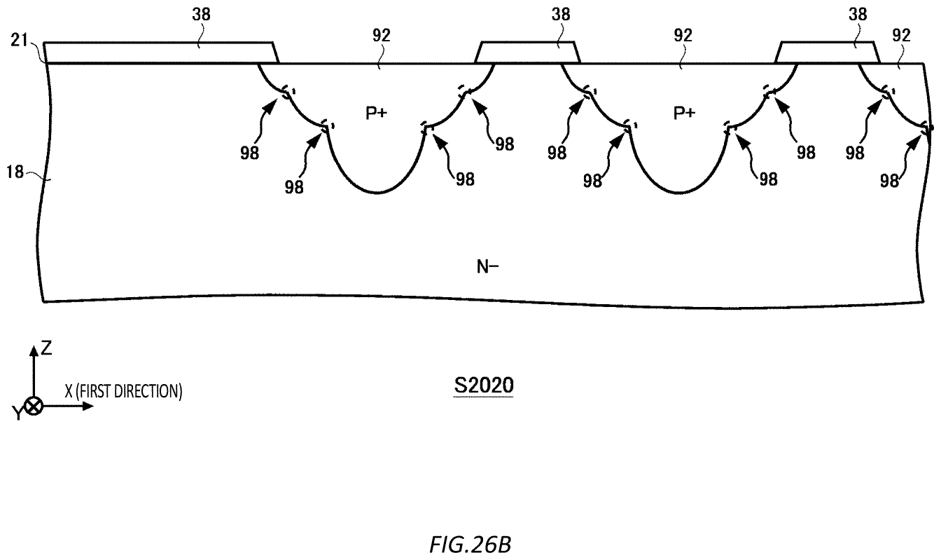

FIG. 26A is a diagram for explaining the implantation step S2010 for the guard ring 92. In the present example, before the implantation step S2010 for the guard ring 92, the interlayer dielectric film 38 is formed on the upper surface 21 of the semiconductor substrate 10, and an opening is formed in the interlayer dielectric film 38. However, the interlayer dielectric film 38 may be formed simultaneously with the formation of the guard ring 92 or in a step after the formation of the guard ring 92.

In the implantation step S2010 for the guard ring 92, the dopant of the guard ring 92 is implanted into a predetermined position of the semiconductor substrate 10. The dopant of the present example is boron. In FIG. 26A, an implantation depth is divided into three stages according to a position in the first direction. In another example, a dose amount may be varied according to the position in the first direction, or the implantation depth and the dose amount may be varied. The type of the bulk dopant of the present example is not particularly limited. Phosphorus or antimony may be used.

FIG. 26B is a diagram for explaining the annealing step S2020. In the annealing step S2020, the dopant is diffused and activated to form the guard ring 92. In a case of the present example, a part of the dopant diffuses below the interlayer dielectric film 38. The shape of the guard ring 92 to be formed changes according to the implantation depth or the like. As a result, the side surface of the guard ring 92 has the inflection point 98.

The shape of the guard ring 92 illustrated in FIG. 26B may be similar to that in FIG. 20. An annealing temperature is, as an example, 1100° C. or lower. Note that although the guard ring 92 of the present example does not have the edge curved surface 102, a guard ring having the edge curved surface 102 may be formed by adjusting the implantation depth and the dose amount of the dopant.

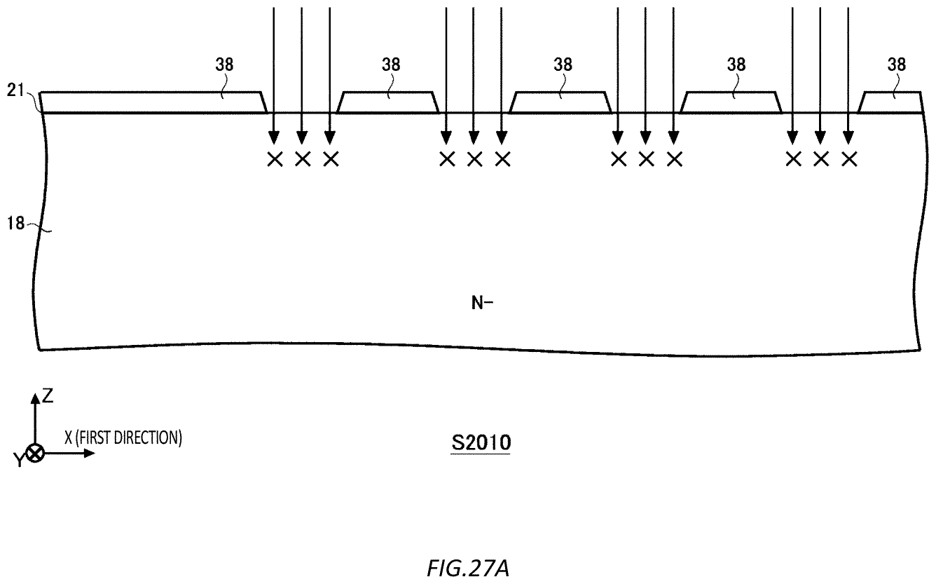

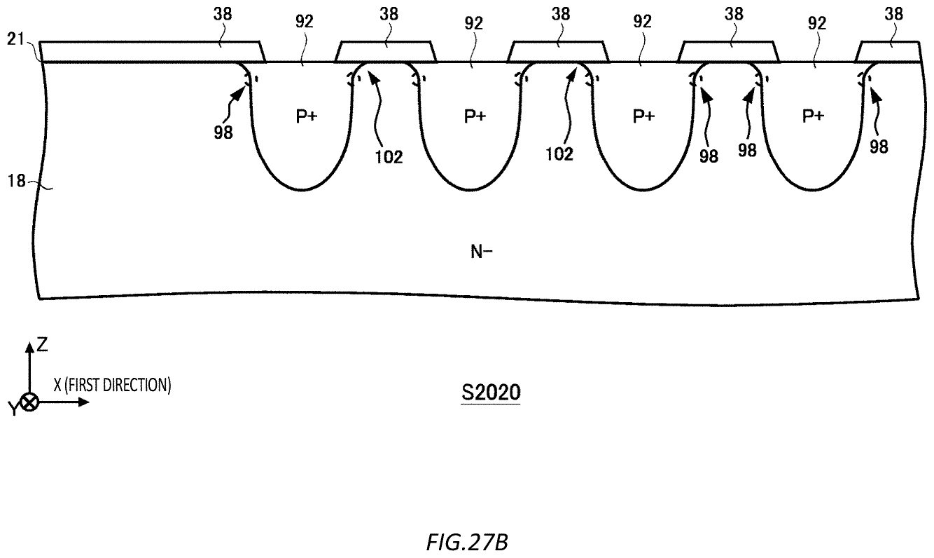

FIG. 27A is a diagram for explaining another example of the implantation step S2010 for the guard ring 92. In the implantation step S2010 for the guard ring 92 of the present example, the implantation depth of the dopant is constant regardless of the position in the first direction. The bulk dopant of the present example is antimony. In addition, the interlayer dielectric film 38 of the present example is formed by oxidizing or nitriding the upper surface 21 of the semiconductor substrate 10.

FIG. 27B is a diagram for explaining another example of the annealing step S2020. In the annealing step S2020 of the present example, the semiconductor substrate 10 in FIG. 27A is annealed. As described above, since the antimony concentration is low in the vicinity of the interlayer dielectric film 38, the junction between the guard ring 92 and the drift region 18 is formed farther from the guard ring 92. As a result, the inflection point 98 and the edge curved surface 102 are formed on the side surface of the guard ring 92. The shape of the guard ring 92 illustrated in FIG. 27B may be similar to that in FIG. 22. In addition, the interlayer dielectric film 38 may be formed simultaneously with the formation of the guard ring 92.

Note that the interlayer dielectric film 38 of the present example may be partially or entirely removed before the ion implantation of the guard ring 92, or may be partially or entirely removed after the formation of the guard ring 92. As a result, the guard ring 92 may not be in contact with the interlayer dielectric film 38. Even when the interlayer dielectric film 38 is removed, the chemical concentration of the bulk dopant of the semiconductor substrate 10 does not change, so that the guard ring 92 having a shape similar to that of FIG. 22 is formed. Note that even when a region of the n type different from the drift region 18 is formed adjacent to the guard ring 92 by ion implantation, the shape of the guard ring 92 similar to that in FIG. 22 may be formed. The region of the n type may be formed by, for example, ion implantation of antimony.

While the present invention has been described by way of the embodiments, the technical scope of the present invention is not limited to the above-described embodiments. It is apparent to persons skilled in the art that various alterations or improvements can be made to the above described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
a semiconductor substrate which has an upper surface and a lower surface and is provided with a drift region of a first conductivity type;
an active portion which is provided in the semiconductor substrate; and
an edge termination structure portion which is provided in the semiconductor substrate and provided between the active portion and an end portion of the semiconductor substrate at the upper surface of the semiconductor substrate, wherein
the edge termination structure portion includes
an interlayer dielectric film which is provided on the upper surface of the semiconductor substrate, and
a guard ring of a second conductivity type which is provided in the semiconductor substrate and is at least partially in contact with the interlayer dielectric film at the upper surface of the semiconductor substrate, and
in a first cross section parallel to both a first direction from the active portion toward the end portion of the semiconductor substrate and a depth direction of the semiconductor substrate, the guard ring has at least one side surface, and the side surface has one or more inflection points.

2. The semiconductor device according to claim 1, wherein
in the first direction, a part of the guard ring between an inflection point, among the one or more inflection points, closest to the interlayer dielectric film and the interlayer dielectric film is wider than a part between the inflection point and a lower end of the guard ring.

3. The semiconductor device according to claim 1, wherein
in the first cross section, the guard ring includes a lower end,
a first side surface on a side of the active portion with respect to the lower end, and
a second side surface on a side of the end portion of the semiconductor substrate with respect to the lower end, and
each of the first side surface and the second side surface has the one or more inflection points.

4. The semiconductor device according to claim 1, wherein
at least one of the inflection points is present on an upper surface side of the semiconductor substrate with respect to a center in a depth direction of the guard ring.

5. The semiconductor device according to claim 1, wherein
the side surface of the guard ring has an edge curved surface that is convex toward the upper surface of the semiconductor substrate in a direction of the interlayer dielectric film, and
the edge curved surface is in contact with the interlayer dielectric film.

6. A semiconductor device comprising:
a semiconductor substrate which has an upper surface and a lower surface and is provided with a drift region of a first conductivity type;
an active portion which is provided in the semiconductor substrate;
an edge termination structure portion which is provided in the semiconductor substrate and provided between the active portion and an end portion of the semiconductor substrate at the upper surface of the semiconductor substrate; and
a well region of a second conductivity type between the active portion and the edge termination structure portion, wherein
the edge termination structure portion includes
an interlayer dielectric film which is provided on the upper surface of the semiconductor substrate, and
a guard ring of the second conductivity type which is provided in the semiconductor substrate and is at least partially in contact with the interlayer dielectric film at the upper surface of the semiconductor substrate,
a depth of the guard ring is deeper than a depth of the well region,
the guard ring includes
a first end portion which is an end portion of the guard ring on a side of the active portion,
a lower end which is at a deepest position of the guard ring, and
a second end portion which is an outer peripheral side end portion of the semiconductor substrate of the guard ring, and
a distance between a position of the lower end and the second end portion in a top view of the semiconductor substrate is larger than a distance between the position of the lower end and the first end portion.

7. The semiconductor device according to claim 6, wherein
a boundary surface between the guard ring and the drift region has a shape that is convex toward the upper surface, between a position of the lower end and a position of the second end portion.

8. The semiconductor device according to claim 6, wherein
the guard ring has a shape of an envelope formed by overlapping a plurality of individual guard rings.

9. The semiconductor device according to claim 1, wherein
the semiconductor substrate contains antimony as a bulk dopant.

10. The semiconductor device according to claim 9, wherein
the interlayer dielectric film includes the bulk dopant.

11. The semiconductor device according to claim 10, wherein
a chemical concentration of the bulk dopant of the interlayer dielectric film at a first position in contact with the upper surface of the semiconductor substrate is higher than a chemical concentration of the bulk dopant of the interlayer dielectric film at a second position farther from the upper surface of the semiconductor substrate than the first position.

12. The semiconductor device according to claim 10, wherein
in the semiconductor substrate, a chemical concentration of the bulk dopant in the drift region is higher than a chemical concentration of the bulk dopant at a position in contact with the interlayer dielectric film.

13. The semiconductor device according to claim 1, wherein
the active portion includes
a gate trench portion which is provided on an upper surface side of the semiconductor substrate and includes a gate conductive portion provided inside the semiconductor substrate and a gate dielectric film insulating the gate conductive portion from the semiconductor substrate,
an adjacent trench portion which is arranged side by side with the gate trench portion in an array direction, and
a base region of the second conductivity type which is provided in a mesa portion which is a region sandwiched between the gate trench portion and the adjacent trench portion, and
a first end portion which is a lower end of the base region at a part in contact with the gate dielectric film is arranged at a position deeper than a second end portion which is a lower end of the base region at a center in the array direction of the mesa portion.

14. The semiconductor device according to claim 13, wherein
in the array direction, a shape of a lower surface of the base region is a curved-surface shape that is convex toward the upper surface of the semiconductor substrate.

15. The semiconductor device according to claim 13, comprising
a trench bottom region of the second conductivity type which is provided apart from the base region and is in contact with a lower end of the gate trench portion, wherein
an upper end of the trench bottom region at a part in contact with the gate dielectric film is located on an upper surface side of the semiconductor substrate with respect to an upper end of the trench bottom region at a center in the array direction of the mesa portion.

16. The semiconductor device according to claim 15, wherein
in the array direction, the upper end of the trench bottom region includes a first curved surface that is convex toward the lower surface of the semiconductor substrate in a direction of the gate dielectric film.

17. The semiconductor device according to claim 2, wherein
the semiconductor substrate contains antimony as a bulk dopant.

18. The semiconductor device according to claim 3, wherein
the semiconductor substrate contains antimony as a bulk dopant.

19. The semiconductor device according to claim 4, wherein
the semiconductor substrate contains antimony as a bulk dopant.

20. The semiconductor device according to claim 6, wherein
the semiconductor substrate contains antimony as a bulk dopant.
